(19) United States
(12) Patent Application Publication
(10) Pub. No.: US 2025/0169098 A1
(43) Pub. Date: May 22, 2025

(54) SEMICONDUCTOR DEVICE

(71) Applicant: SAMSUNG ELECTRONICS CO., LTD., Suwon-si (KR)

(72) Inventors: Junhyuk PARK, Suwon-si (KR); Jongseob KIM, Suwon-si (KR); Joonyong KIM, Suwon-si (KR); Seong Seok YANG, Suwon-si (KR); Jaejoon OH, Suwon-si (KR)

(73) Assignee: SAMSUNG ELECTRONICS CO., LTD., Suwon-si (KR)

(21) Appl. No.: 18/680,609

(22) Filed: May 31, 2024

(30) Foreign Application Priority Data
Nov. 20, 2023 (KR) 10-2023-0161054

(51) Int. Cl. H01L 29/778; H01L 29/20; H01L 29/423; H01L 29/66

(52) U.S. Cl. CPC H10D 30/4755; H10D 30/015; H10D 62/8503; H10D 64/411

(57) ABSTRACT

A semiconductor device according to an embodiment includes a channel layer; a barrier layer above the channel layer and including a material having a different energy band gap than the channel layer; a gate electrode above the barrier layer; a gate semiconductor layer between the barrier layer and the gate electrode; a source electrode and a drain electrode on respective sides of the gate electrode and on respective sides of the channel layer and the barrier layer; a field dispersion layer connected to the source electrode and on the gate electrode; and a protection layer between barrier layer and the field dispersion layer, wherein the protection layer includes a first protection layer above the barrier layer and including silicon oxide, and a second protection layer positioned above the first protection layer and including silicon oxynitride.

### CROSS-REFERENCE TO RELATED APPLICATION

This application claims priority to and the benefit of Korean Patent Application No. 10-2023-0161054, filed in the Korean Intellectual Property Office on Nov. 20, 2023, the entire contents of which are incorporated herein by reference.

### BACKGROUND

### 1. Field

Embodiments of the present disclosure relate to a semiconductor device.

### 2. Description of the Related Art

In modern society, semiconductor devices are closely related to daily life. In particular, importance of electric power semiconductor devices used in various fields such as transportation fields such as electric vehicles, railways, and electric trams; renewable energy systems such as solar power generation and wind power generation; and mobile devices is gradually increasing. An electric power semiconductor device is a semiconductor device used to handle high voltage or high current, and performs functions such as an electric power conversion and control in large electric power systems or high power electronic devices. The electric power semiconductor devices have an ability and durability to handle high electric power, including handling large amounts of a current and withstanding high voltages. For example, the electric power semiconductor device may handle voltages of hundreds to thousands of volts and currents of tens of amperes to thousands of amperes. The electric power semiconductor devices may improve electrical energy efficiency by minimizing a power loss. Additionally, the electric power semiconductor devices may be operated stably even in environments such as high temperature.

These electric power semiconductor devices may be classified according to a material, and examples include a SiC electric power semiconductor device and a GaN electric power semiconductor device. By manufacturing the electric power semiconductor devices by using SiC or GaN instead of existing silicon wafers (Si wafers), a drawback of silicon, which has unstable characteristics at high temperatures, may be compensated. The SiC electric power semiconductor devices are resistant to high temperatures and have low power loss, and may be suitable for the electric vehicles, the renewable energy systems, etc. The GaN electric power semiconductor devices require high costs, but are efficient in terms of speed and may be suitable for high-speed charging of the mobile devices.

### SUMMARY

According to embodiments of the present disclosure, a semiconductor device with stable electric characteristics and improved reliability is provided.

According to embodiments of the present disclosure, a semiconductor device is provided and includes: a channel layer; a barrier layer above the channel layer and including a material having a energy band gap that is different from an energy band gap of the channel layer; a gate electrode above the barrier layer, a gate semiconductor layer between the barrier layer and the gate electrode; a source electrode on a first side of the gate electrode, and on a first side of the channel layer and a first side of the barrier layer; a drain electrode on a second side of the gate electrode, opposite to the first side, and on a second side of the channel layer and a second side of the barrier layer; and a field dispersion layer connected to the source electrode and on the gate electrode, and a protection layer between barrier layer and the field dispersion layer, wherein the protection layer includes a first protection layer above the barrier layer and including silicon oxide; and a second protection layer above the first protection layer and including silicon oxynitride.

According to embodiments of the present disclosure, a semiconductor device is provided and includes: a channel layer; a barrier layer above the channel layer and including a material having an energy band gap that is different from an energy band gap of the channel layer; a gate semiconductor layer above the barrier layer; a protection layer on the barrier layer and the gate semiconductor layer; a source electrode on a first side of the channel layer and a first side of the barrier layer; and a drain electrode on a second side of the channel layer and a second side of the barrier layer, wherein the protection layer includes a first protection layer above the barrier layer and including a first element, and a second protection layer above the first protection layer and including the first element and a second element different from the first element, and wherein a ratio of the first element of the first protection layer increases in a direction away from an upper surface of the barrier layer.

According to embodiments of the present disclosure, a semiconductor device is provided and includes: a substrate; a channel layer on the substrate and including GaN; a barrier layer above the channel layer and including AlGaN; a gate electrode above the barrier layer and including a metal material; a gate semiconductor layer between the barrier layer and the gate electrode and including GaN doped with a P-type impurity; a source electrode on a first side of the gate electrode, and on a first side of the channel layer and a first side of the barrier layer; a drain electrode on a second side of the gate electrode, opposite to the first side, and on a second side of the channel layer and a second side of the barrier layer; a field dispersion layer on the gate electrode, the field dispersion layer in a same layer as a layer of the source electrode and formed integrally with the source electrode; and a protection layer between the barrier layer and the field dispersion layer, wherein the protection layer includes a first protection layer on the barrier layer and including Si, and a second protection layer on the first protection layer and including SiON, and wherein an Si ratio of the first protection layer increases in a direction away from an upper surface of the barrier layer.

According to embodiments of the present disclosure, electric characteristics and a reliability of the semiconductor device may be improved.

### BRIEF DESCRIPTION OF DRAWINGS

FIG. 1 and FIG. 2 are cross-sectional views showing a semiconductor device according to an embodiment.

FIG. 3 to FIG. 12 are cross-sectional views showing a semiconductor device according to several embodiments.

FIG. 13 to FIG. 18 are process cross-sectional views shown according to a process order of manufacturing a semiconductor device according to an embodiment.

FIG. 19 to FIG. 24 are process cross-sectional views shown according to a process order of manufacturing a semiconductor device according to some embodiments.

### DETAILED DESCRIPTION

Non-limiting example embodiments of the present disclosure will be described more fully hereinafter with reference to the accompanying drawings, in which example embodiments of the disclosure are shown. As those skilled in the art would realize, the described example embodiments may be modified in various different ways, all without departing from the spirit or scope of the present disclosure.

In order to clearly describe the present disclosure, portions that are not connected with the description may be omitted. Like reference numerals designate like elements throughout the specification.

In addition, the size and thickness of each configuration shown in the drawings may be arbitrarily shown for understanding and ease of description, but embodiments of the present disclosure are not limited thereto. In the drawings, the thickness of layers, films, panels, regions, etc., may be exaggerated for clarity. In the drawings, the thickness of layers, films, panels, regions, etc., may be exaggerated for the convenience of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, the word “over” or “on” means positioning on or below the object portion, and does not necessarily mean positioning on the upper side of the object portion based on a gravity direction.

In addition, unless explicitly described to the contrary, the word “comprise” (or “include”), and variations such as “comprises” (or “includes”) or “comprising” (or “including”), will be understood to imply the inclusion of stated elements but not the exclusion of any other elements.

Further, in the specification, the phrase “on a plane” means viewing the main surface (e.g., a surface where an image is displayed) of the object portion from the top, and the phrase “on a cross-section” means viewing a cross-section of which the object portion is vertically cut from the side.

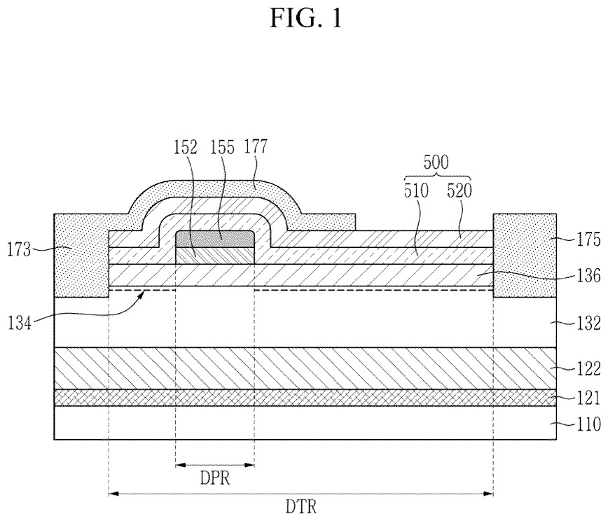

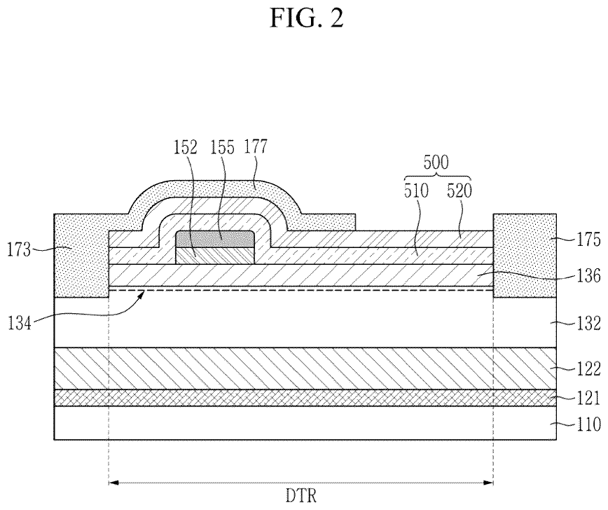

Hereinafter, a description of the semiconductor device according to an embodiment is described with reference to FIG. 1 and to FIG. 2 as follows.

FIG. 1 and FIG. 2 are cross-sectional views showing a semiconductor device according to an embodiment. FIG. 1 represents a case where the semiconductor device according to an embodiment is in an off state. FIG. 2 represents a case where the semiconductor device according to an embodiment is in an on state.

First, as shown in FIG. 1, the semiconductor device according to an embodiment may include a channel layer 132, a barrier layer 136 placed on the channel layer 132, a gate electrode 155 placed on the barrier layer 136, a gate semiconductor layer 152 placed between the barrier layer 136 and the gate electrode 155, a protection layer 500 placed on the barrier layer 136, a source electrode 173 and a drain electrode 175 separated from each other on the channel layer 132, and a field dispersion layer 177 placed on the protection layer 500.

The channel layer 132 is a layer that forms a channel between the source electrode 173 and the drain electrode 175, and a two-dimensional electron gas (2DEG) 134 may be positioned inside the channel layer 132. The two-dimensional electron gas 134 is a charge transport model used in solid physics, and refers to a group of electrons that can move freely in a two-dimensional (e.g., a x-y planar direction) but cannot move in another dimension (e.g., a z direction) and are tightly bound within a two-dimensional space. In other words, the two-dimensional electron gas 134 may exist in a two-dimensional paper-like form within a three-dimensional space. This two-dimensional electron gas 134 mainly appears in a semiconductor heterojunction structure, and may occur at the interface between the channel layer 132 and the barrier layer 136 in the semiconductor device according to an embodiment. For example, the two-dimensional electron gas 134 may be generated in the portion closest to the barrier layer 136 within the channel layer 132.

The channel layer 132 may include one or more materials selected from Group III-V materials, such as nitrides including Al, Ga, In, B, or combinations thereof. The channel layer 132 may be composed of a single layer or multiple layers. The channel layer 132 may be AlₓIn_{y}Ga_{(1-x-y)}N (0≤x≤1, 0≤y≤1, x+y≤1). For example, the channel layer 132 may be AlN, GaN, InN, InGaN, AlGaN, AlInN, AlInGaN, or a combination thereof. The channel layer 132 may be a layer with a doped impurity or a layer with a undoped impurity. The thickness of the channel layer 132 may be about several hundred nm or less.

The channel layer 132 may be positioned on a substrate 110, and a seed layer 121 and a buffer layer 122 may be positioned between the substrate 110 and the channel layer 132. The substrate 110, the seed layer 121, and the buffer layer 122 are layers for forming the channel layer 132, and may be omitted in some cases. For example, when a substrate made of GaN is used as the channel layer 132, at least one from among the substrate 110, the seed layer 121, and the buffer layer 122 may be omitted. Considering that the price of a substrate made of GaN is relatively high, the channel layer 132 including GaN may be grown using the substrate 110 made of Si. Because a lattice structure of Si and a lattice structure of GaN are different, it may not be easy to grow the channel layer 132 directly on the substrate 110. Accordingly, after growing the seed layer 121 and the buffer layer 122 on the substrate 110, the channel layer 132 may be grown on the buffer layer 122. Additionally, at least one from among the substrate 110, the seed layer 121, and the buffer layer 122 may be removed from the final structure of the semiconductor device after being used in the manufacturing process.

The substrate 110 may include a semiconductor material. For example, the substrate 110 may include sapphire, Si, SiC, AlN, GaN, or a combination thereof. The substrate 110 may be a silicon on insulator (SOI) substrate. However, the material of the substrate 110 is not limited to this, and any generally-used substrate may be applied. In some cases, the substrate 110 may include an insulating material. For example, after forming several layers, including the channel layer 132, on the semiconductor substrate, the semiconductor substrate may then be removed to be replaced with an insulation substrate.

The buffer layer 122 may be positioned on the substrate 110. The seed layer 121 may be further positioned between the substrate 110 and the buffer layer 122. The seed layer 121 may be positioned directly above the substrate 110. However, embodiments of the present disclosure are not limited to this, and another predetermined layer may be further positioned between the substrate 110 and the seed layer 121. The seed layer 121 is a layer that serves as a seed for growing the buffer layer 122, and may be made of a crystal lattice structure that becomes the seed of the buffer layer 122. The buffer layer 122 may be positioned directly above the seed layer 121. However, embodiments of the present disclosure are not limited to this, and another predetermined layer may be positioned between the seed layer 121 and the buffer layer 122. As an embodiment, the seed layer 121 may include AlN.

The buffer layer 122 may be positioned between the substrate 110 and the channel layer 132. The buffer layer 122 is a layer to alleviate differences in lattice constants and thermal expansion coefficients between the substrate 110 and the channel layer 132. The buffer layer 122 may include one or more materials selected from Group Ill-V materials, such as nitrides including Al, Ga, In, B, or combinations thereof. The buffer layer 122 may be AlₓIn_{y}Ga_{(1-x-y)}N (0≤x≤1, 0≤y≤1, x+y≤1). For example, the buffer layer 122 may include AlN, GaN, InN, InGaN, AlGaN, AlInN, AlInGaN, or combination thereof. The buffer layer 122 may be composed of a single layer or multiple layers.

The buffer layer 122 of the semiconductor device according to an embodiment may further include a superlattice layer and/or a high-resistance layer. The superlattice layer and the high-resistance layer may be positioned sequentially on the seed layer 121.

The superlattice layer may be positioned above the seed layer 121. The superlattice layer may be positioned directly above the seed layer 121. However, embodiments of the present disclosure are not limited to this, and another predetermined layer may be positioned between the seed layer 121 and the superlattice layer. The superlattice layer is a layer to alleviate the difference in lattice constants and thermal expansion coefficients between the substrate 110 and the channel layer 132. The superlattice layer may include one or more materials selected from Group Ill-V materials, such as nitrides including Al, Ga, In, B, or combinations thereof. The superlattice layer may be AlₓIn_{y}Ga_{(1-x-y)}N (0≤x≤1, 0≤y≤1, x+y≤1). For example, the superlattice layer may include AlN, GaN, InN, InGaN, AlGaN, AlInN, AlInGaN, or combinations thereof. The superlattice layer may be composed of a single layer or multiple layers. For example, the superlattice layer may have a structure in which a layer made of AlGaN and a layer made of GaN are repeatedly stacked. For example, AlGaN/GaN/AlGaN/GaN/AlGaN/GaN may be sequentially stacked to form a superlattice layer. The number of AlGaN layers and GaN that make up the superlattice layer can be changed in various ways, and the material that makes up the superlattice layer may be changed in various ways.

The high-resistance layer may be positioned above the superlattice layer. The high-resistance layer may be positioned directly above the superlattice layer. However, embodiments of the present disclosure are not limited to this, and another predetermined layer may be positioned between the superlattice layer and the high-resistance layer. The high-resistance layer may be positioned between the superlattice layer and the channel layer 132. The high-resistance layer may be a layer to prevent the semiconductor device according to an embodiment, including the channel layer 132, from being influenced by the outside. The high-resistance layer may be made of a material with low conductivity so that the substrate 110 and the channel layer 132 are electrically insulated. The high-resistance layer may include one or more materials selected from Group III-V materials, such as nitrides including Al, Ga, In, B, or combinations thereof. The high-resistance layer may be AlₓIn_{y}Ga_{1-x-y}N (0≤x≤1, 0≤y≤1, x+y≤1). For example, the high-resistance layer may include AlN, GaN, InN, InGaN, AlGaN, AlInN, AlInGaN, or combinations thereof. The high-resistance layer may be made of a single layer or multiple layers. The high-resistance layer may be a layer in which an impurity is not doped.

The barrier layer 136 may be positioned above the channel layer 132. The barrier layer 136 may be positioned directly above the channel layer 132. However, embodiments of the present disclosure are not limited to this, and another predetermined layer may be positioned between the channel layer 132 and the barrier layer 136. The region of the channel layer 132 that overlaps with the barrier layer 136 may become a drift region DTR. The drift region DTR may be positioned between the source electrode 173 and the drain electrode 175. The drift region DTR may mean a region to which carriers move when a potential difference occurs between the source electrode 173 and the drain electrode 175.

The semiconductor device according to an embodiment may be turned on/off depending on whether a voltage is applied to the gate electrode 155 and/or the size of the voltage applied to the gate electrode 155, and accordingly, a movement of carriers in the drift region DTR may be achieved or blocked.

The barrier layer 136 may include one or more materials selected from Group III-V materials, such as nitrides including Al, Ga, In, B, or combinations thereof. The barrier layer 136 may be AlₓIn_{y}Ga_{1-x-y}N (0≤x≤1, 0≤y≤1, x+y≤1). The barrier layer 136 may include GaN, InN, AlGaN, AlInN, InGaN, AlN, AlInGaN or combination thereof. The energy band gap of the barrier layer 136 may be adjusted by a composition ratio of Al and/or In. The barrier layer 136 may be doped with a predetermined impurity. In such case, the impurity doped in the barrier layer 136 may be a P-type dopant that can provide a hole. For example, the impurity doped in the barrier layer 136 may be magnesium (Mg). By increasing or decreasing the impurity doping concentration of the barrier layer 136, a threshold voltage, an on-resistance, etc. of the semiconductor device according to an embodiment may be adjusted.

The barrier layer 136 may include a semiconductor material with characteristics different from characteristics of the channel layer 132. The barrier layer 136 may differ from the channel layer 132 in at least one from among a polarization characteristic, an energy band gap, and a lattice constant. For example, the barrier layer 136 may include a material having a different energy band gap from the channel layer 132. In such case, the barrier layer 136 may have a higher energy band gap than the channel layer 132 and may have a higher electrical polarization rate than the channel layer 132. This barrier layer 136 may cause a two-dimensional electron gas 134 in the channel layer 132, which has a relatively low electrical polarization rate. In this respect, the barrier layer 136 may also be called a channel supply layer or a two-dimensional electron gas supply layer. The two-dimensional electron gas 134 may be formed within a portion of the channel layer 132 positioned below the interface between the channel layer 132 and the barrier layer 136. The two-dimensional electron gas 134 may have a very high electron mobility.

The barrier layer 136 may be composed of a single layer or multiple layers. If the barrier layer 136 is made of multiple layers, the energy band gap of the material of each layer constituting the multiple layers may be different. In such case, the multiple layers constituting the barrier layer 136 may be arranged so that the energy band gap increases as it approaches the channel layer 132.

The gate electrode 155 may be positioned on the barrier layer 136. The gate electrode 155 may overlap with some regions of the barrier layer 136. The gate electrode 155 may overlap with a part of the drift region DTR of the channel layer 132. The gate electrode 155 may be positioned between the source electrode 173 and the drain electrode 175. The gate electrode 155 may be separated from the source electrode 173 and the drain electrode 175. For example, the gate electrode 155 may be positioned closer to the source electrode 173 than the drain electrode 175. In other words, the separation distance between the gate electrode 155 and the source electrode 173 may be smaller than the separation distance between the gate electrode 155 and the drain electrode 175, but embodiments of the present disclosure are not limited thereto.

The gate electrode 155 may include a conductive material. For example, the gate electrode 155 may include a metal, a metal alloy, a conductive metal nitride, a metal silicide, a doped semiconductor material, a conductive metal oxide, or a conductive metal oxynitride. For example, the gate electrode 155 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonizationnitride (TiAlC-N), titanium aluminum carbide (TiAlC), titanium carbide (TiC), tantalum carbonizationnitride (TaCN), tungsten (W), aluminum (AI), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combination thereof, but it is not thereto. The gate electrode 155 may be made of a single layer or multiple layers.

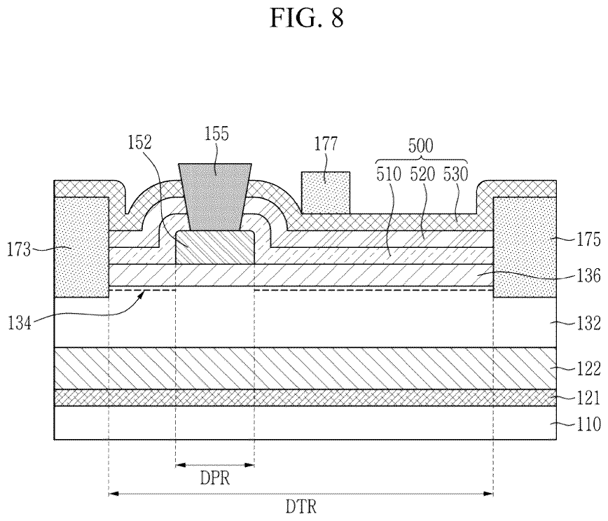

The gate semiconductor layer 152 may be positioned between the barrier layer 136 and the gate electrode 155. That is, the gate semiconductor layer 152 may be positioned on the barrier layer 136, and the gate electrode 155 may be positioned on the gate semiconductor layer 152. The gate electrode 155 may be in Schottky contact or ohmic contact with the gate semiconductor layer 152. The gate semiconductor layer 152 may overlap with the gate electrode 155. In such case, the gate semiconductor layer 152 may completely overlap with the gate electrode 155 in the vertical direction, and the upper surface of the gate semiconductor layer 152 may be entirely covered by the gate electrode 155. That is, the gate semiconductor layer 152 may have substantially the same planar shape as the planar shape of the gate electrode 155. However, embodiments of the present disclosure are not limited thereto, the gate electrode 155 may be positioned to cover at least a part of the gate semiconductor layer 152. This is described later with reference to FIG. 8.

The gate semiconductor layer 152 may be positioned between the source electrode 173 and the drain electrode 175. The gate semiconductor layer 152 may be separated from the source electrode 173 and the drain electrode 175. The gate semiconductor layer 152 may be positioned closer to the source electrode 173 than the drain electrode 175. In other words, the separation distance between the gate semiconductor layer 152 and the source electrode 173 may be smaller than the separation distance between the gate semiconductor layer 152 and the drain electrode 175, but is not limited thereto.

In an embodiment, the gate semiconductor layer 152 may overlap with the gate electrode 155 in a vertical direction (e.g., the thickness direction of the channel layer 132). For example, the gate semiconductor layer 152 may completely overlap with the gate electrode 155 in the vertical direction (e.g., the thickness direction of the channel layer 132). That is, the side of the gate semiconductor layer 152 may be aligned with the side of the gate electrode 155. However, embodiments of the present disclosure are not limited thereto, and the gate semiconductor layer 152 may partially overlap with the gate electrode 155. This is described later with reference to FIG. 8 to FIG. 11.

The gate semiconductor layer 152 may include one or more materials selected from Group III-V materials, such as nitrides including Al, Ga, In, B, or combinations thereof. The gate semiconductor layer 152 may be AlₓIn_{y}Ga_{1-x-y}N (0≤x≤1, 0≤y≤1, x+y≤1). For example, the gate semiconductor layer 152 may include AlN, GaN, InN, InGaN, AlGaN, AlInN, AlInGaN, or a combination thereof. The gate semiconductor layer 152 may include a material having a different energy band gap from the barrier layer 136. For example, the gate semiconductor layer 152 may include GaN, and the barrier layer 136 may include AlGaN. The gate semiconductor layer 152 may be doped with a predetermined impurity. In such case, the impurity doped in the gate semiconductor layer 152 may be a P-type dopant that can provide a hole. For example, the gate semiconductor layer 152 may include GaN doped with a P-type impurity. That is, the gate semiconductor layer 152 may be made of a p-GaN layer. However, embodiments of the present disclosure are not limited to this, and the gate semiconductor layer 152 may be a p-AlGaN layer. The impurity doped in the gate semiconductor layer 152 may be magnesium (Mg). In such case, when the doped impurity (e.g., magnesium) within the gate semiconductor layer 152 is combined with an adjacent predetermined element, the hole concentration within the gate semiconductor layer 152 may be reduced, and the characteristics of the semiconductor device may be degraded accordingly. The gate semiconductor layer 152 may be made of a single layer or multiple layers. The impurity doped into the gate semiconductor layer 152 may be magnesium (Mg).

A depletion region DPR may be formed within the channel layer 132 by the gate semiconductor layer 152. The depletion region DPR may be positioned within the drift region DTR and may have a narrower width than a width of the drift region DTR. As the gate semiconductor layer 152, which has the different energy band gap from that of the barrier layer 136, is positioned on the barrier layer 136, the level of the energy band of the portion of the barrier layer 136 that overlaps the gate semiconductor layer 152 may increase. Accordingly, the depletion region DPR may be formed in the region of the channel layer 132 that overlaps with the gate semiconductor layer 152. The depletion region DPR may be a region in the channel path of the channel layer 132 in which the two-dimensional electron gas 134 is not formed or has a lower electron concentration than electron concentrations in the remaining regions. In other words, the depletion region DPR may mean a region where the flow of the two-dimensional electron gas 134 is disconnected within the drift region DTR. As the depletion region DPR occurs, a current does not flow between the source electrode 173 and the drain electrode 175, and the channel path may be blocked. Accordingly, the semiconductor device according to an embodiment may have a normally off characteristic.

That is, the semiconductor device according to an embodiment may be a normally off high electron mobility transistor (HEMT). As shown in FIG. 1, In a normal state in which no voltage is applied to the gate electrode 155, the depletion region DPR exists, and the semiconductor device according to an embodiment may be in an off state. As shown in FIG. 2, when a voltage higher than a threshold voltage is applied to the gate electrode 155, the depletion region DPR disappears, and the two-dimensional electron gas 134 within the drift region DTR is not disconnected and may be connected. That is, the two-dimensional electron gas 134 may be formed throughout the channel path between the source electrode 173 and the drain electrode 175, and the semiconductor device according to an embodiment may be in an on state. In summary, the semiconductor device according to an embodiment may include the semiconductor layers with different electrical polarization characteristics, and the semiconductor layer with the relatively high polarization rate may induce the two-dimensional electron gas 134 in another semiconductor layer heterogeneously jointed thereto. This two-dimensional electron gas 134 may be used as a channel between the source electrode 173 and the drain electrode 175, and the connection or disconnection of the flow of this two-dimensional electron gas 134 may be controlled by the bias voltage applied to the gate electrode 155. In the gate off state, the flow of the two-dimensional electron gas 134 is blocked, so a current may not flow between the source electrode 173 and the drain electrode 175. As the flow of the two-dimensional electron gas 134 continues in the gate on state, a current may flow between the source electrode 173 and the drain electrode 175.

The seed layer 121, the buffer layer 122, the channel layer 132, the barrier layer 136, and the gate semiconductor layer 152 previously described may be sequentially stacked on the substrate 110. In the semiconductor device according to an embodiment, at least one from among the seed layer 121, the buffer layer 122, the channel layer 132, the barrier layer 136, and the gate semiconductor layer 152 may be omitted. The seed layer 121, the buffer layer 122, the channel layer 132, the barrier layer 136, and the gate semiconductor layer 152 may be made of the semiconductor material of the same elements, and considering the role of each layer and the performance required for the semiconductor device, the material composition ratio of each layer may be different.

The protection layer 500 may be positioned above the barrier layer 136 and the gate electrode 155. The protection layer 500 may cover the upper and side surfaces of the gate electrode 155 and the side surfaces of the gate semiconductor layer 152. The lower surface of the protection layer 500 is in contact with the barrier layer 136 and the gate electrode 155. Accordingly, the barrier layer 136, the gate semiconductor layer 152, and the gate electrode 155 may be protected by the protection layer 500. However, embodiments of the present disclosure are not limited thereto. For example, the gate electrode 155 may penetrate the protection layer 500 and be connected to the gate semiconductor layer 152, and the protection layer 500 may not cover the upper surface of the gate electrode 155. Alternatively, the lower surface of the protection layer 500 may be in contact with the gate semiconductor layer 152. This is described with reference to FIG. 8 later.

The protection layer 500 of the semiconductor device according to an embodiment may include a first protection layer 510 and a second protection layer 520 positioned above the first protection layer 510.

The first protection layer 510 may be placed on the barrier layer 136. The first protection layer 510 may cover the barrier layer 136. For example, the first protection layer 510 may be placed on the barrier layer 136 between the source electrode 173 and the drain electrode 175. The first protection layer 510 may overlap with the drift region DTR of the channel layer 132 in the vertical direction (e.g., the thickness direction of the channel layer 132). The first protection layer 510 may cover the upper and side surfaces of the gate electrode 155 and the side surface of the gate semiconductor layer 152. The lower surface of the first protection layer 510 may be in contact with the barrier layer 136 and the gate electrode 155. The side of the first protection layer 510 may be in contact with the source electrode 173 and the drain electrode 175. However, embodiments of the present disclosure are not limited thereto. For example, the gate electrode 155 may penetrate the first protection layer 510 and be connected to the gate semiconductor layer 152, and the first protection layer 510 may not cover the upper surface of the gate electrode 155. Alternatively, the lower surface of the first protection layer 510 may be in contact with the gate semiconductor layer 152. This is described with reference to FIG. 8 later.

In an embodiment, the first protection layer 510 may be positioned between the barrier layer 136 and the field dispersion layer 177, which will be described later. At least a portion of the first protection layer 510 may overlap with the field dispersion layer 177 in the vertical direction (e.g., the thickness direction of the channel layer 132). Accordingly, the portion of the first protection layer 510 that overlaps with the field dispersion layer 177 in the vertical direction (e.g., the thickness direction of the channel layer 132) may cover the gate semiconductor layer 152 and the gate electrode 155.

In an embodiment, the first protection layer 510 may include an insulating material. For example, the first protection layer 510 may include silicon oxide (SiOₓ) (1≤x≤4). Also, the first protection layer 510 may include a material such as silicon nitride (SiN) or aluminum oxide (Al₂O₃).

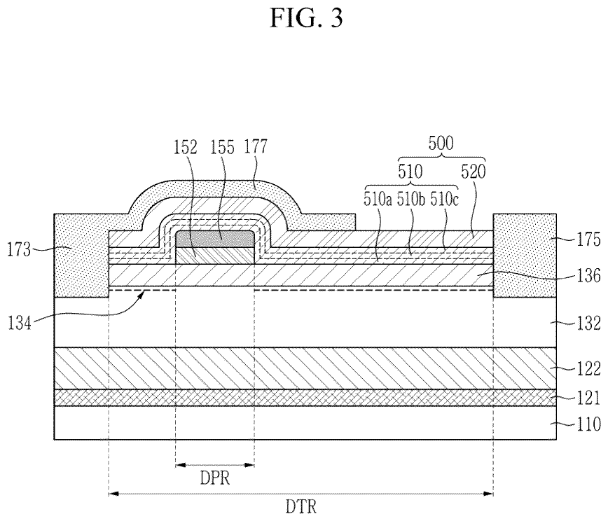

In an embodiment, the first protection layer 510 may include a first element. For example, when the first protection layer 510 of a semiconductor device according to an embodiment includes silicon oxide (SiOₓ) (1≤x≤4), the first element may be silicon (Si). In such case, the first protection layer 510 may include a plurality of regions of which the ratio of the first element is different. For example, the ratio of the first element of the lower part of the first protection layer 510 may be smaller than the ratio of the first element of the upper part of the first protection layer 510. Alternatively, the ratio of the first element of the first protection layer 510 may increase as it moves away from the upper surface of the barrier layer 136. Here, the ratio of the first element of the first protection layer 510 may mean the ratio of the first element for the material constituting the first protection layer 510 in a first region 510a, a second region 510b, and a third region 510c (see FIG. 3). For example, the fraction of the first element may mean a mass percentage (wt %), a mole percentage (mol %), an atom percentage (at %), etc.

For example, the lower part of the first protection layer 510 may include silicon oxide (SiOₓ₁, 1≤x1≤4), and the upper part of the first protection layer 510 may include silicon oxide (SiOₓ₂, 1≤x2≤4). Here, the first element is silicon (Si), and x1 may be larger than x2. In other words, the ratio of oxygen atoms combining with silicon (Si) in a unit number in the lower part of the first protection layer 510 may be greater than the ratio of oxygen atoms combining with silicon (Si) in a unit number in the upper part of the first protection layer 510. This may mean that the ratio of the first element in the lower part of the first protection layer 510 may be smaller than the ratio of the first element in the upper part of the first protection layer 510. The detailed description of this is provided later with reference to FIG. 3.

In an embodiment, it was explained that the first element included in the first protection layer 510 is silicon (Si), but embodiments of the present disclosure are not limited thereto. The first element may vary depending on the material included in the first protection layer 510.

As the ratio of the first element of the first protection layer 510 of the semiconductor device according to an embodiment increases as the distance from the upper surface of the barrier layer 136 increases, external impurities generated in the process of forming the first protection layer 510 may be prevented from penetrating into the gate semiconductor layer 152. Accordingly, charges may be concentrated within the drift region DTR. In other words, the semiconductor device according to an embodiment may have stable electric characteristics and a reliability may be improved.

The second protection layer 520 may be positioned above the first protection layer 510. The second protection layer 520 may cover the first protection layer 510. For example, the second protection layer 520 may be positioned on the first protection layer 510 between the source electrode 173 and the drain electrode 175. The second protection layer 520 may overlap the drift region DTR of channel layer 132 in the vertical direction (e.g., the thickness direction of the channel layer 132). The upper surface of the second protection layer 520 may be in contact with the lower surface of the field dispersion layer 177. The second protection layer 520 may not be in contact with the gate electrode 155 and the gate semiconductor layer 152, but embodiments of the present disclosure are not limited thereto. The lower surface of the second protection layer 520 may be in contact with the first protection layer 510. The side of the second protection layer 520 may be in contact with the source electrode 173 and the drain electrode 175. However, embodiments of the present disclosure are not limited thereto, and the second protection layer 520 may cover the upper surface of the source electrode 173 and the drain electrode 175. An explanation of this is provided later with reference to FIG. 8.

In an embodiment, the second protection layer 520 may be positioned between the first protection layer 510 and the field dispersion layer 177, which will be described later. At least a portion of the second protection layer 520 may overlap with the field dispersion layer 177 in the vertical direction (e.g., the thickness direction of the channel layer 132).

In an embodiment, the second protection layer 520 may include an insulating material. The second protection layer 520 may include a material different from a material of the first protection layer 510. For example, the second protection layer 520 may include silicon oxynitride (SiON), but embodiments of the present disclosure are not limited thereto. For example, the second protection layer 520 may include a first element and a second element different from the first element. For example, when the second protection layer 520 of the semiconductor device according to an embodiment includes silicon oxynitride (SiON), the first element may be silicon (Si) and the second element may be nitrogen (N).

The second protection layer 520 of the semiconductor device according to an embodiment may include a first element and a second element different from the first element. If the second element is included in the second protection layer 520, the density of charge within the drift region DTR may increase. Meanwhile, when forming the second protection layer 520 to be in contact with the gate semiconductor layer 152, in the process of forming the second protection layer 520, a specific element included in the second protection layer 520 may be combined with an impurity (e.g., magnesium) doped within the gate semiconductor layer 152. In this case, the hole concentration within the gate semiconductor layer 152 may be reduced and the characteristics of the semiconductor device may be degraded.

The second protection layer 520 of the semiconductor device according to an embodiment is positioned above the first protection layer 510, so that the gate semiconductor layer 152 and the second protection layer 520 may not be in contact. Accordingly, it is possible to prevent the hole concentration within the gate semiconductor layer 152 from being reduced during the process of forming the second protection layer 520. In other words, it is possible to prevent a decrease in the density of the two-dimensional electron gas 134 formed within the channel layer 132, and to prevent characteristic degradations such as an on-current and an on-resistance. In addition, the second protection layer 520 may prevent electrons and holes of the semiconductor device from leaking to the outside, and may prevent moisture or oxygen from penetrating into the channel layer 132. In other words, the semiconductor device according to an embodiment may have stable electric characteristics and a reliability may be improved.

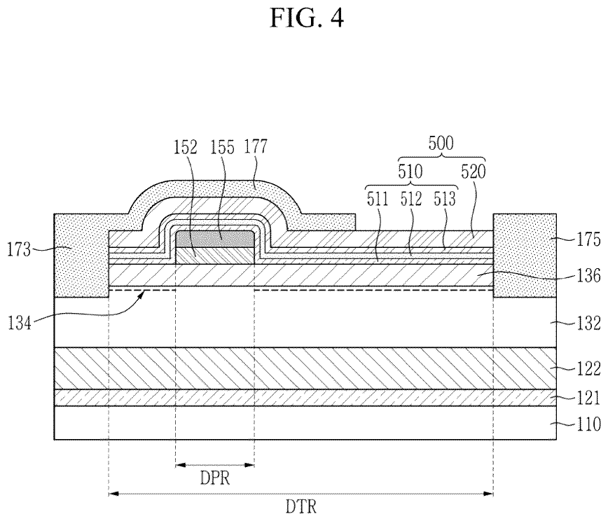

In an embodiment, the first protection layer 510 and the second protection layer 520 may be comprised of a single layer or multiple layers. For example, in some cases, at least one from among the first protection layer 510 and the second protection layer 520 may include two or more layers. This is described later with reference to FIG. 4.

The source electrode 173 and the drain electrode 175 may be positioned above the channel layer 132. The source electrode 173 and the drain electrode 175 may be in direct contact with the channel layer 132 and electrically connected to the channel layer 132. The source electrode 173 and the drain electrode 175 may be spaced apart from each other, and the gate electrode 155 and the gate semiconductor layer 152 may be positioned between the source electrode 173 and the drain electrode 175. The gate electrode 155 and the gate semiconductor layer 152 may be separated from the source electrode 173 and the drain electrode 175. For example, the source electrode 173 may be electrically connected to the channel layer 132 on one side of the gate electrode 155, and the drain electrode 175 may be electrically connected to the channel layer 132 on the other side of the gate electrode 155. The source electrode 173 and the drain electrode 175 may be positioned outside of the drift region DTR of the channel layer 132. The interface between the source electrode 173 and the channel layer 132 may be one edge of the drift region DTR. Likewise, the interface between the drain electrode 175 and the channel layer 132 may be the other edge of the drift region DTR.

Specifically, a trench that penetrates the protection layer 500 and the barrier layer 136 and recesses the upper surface of the channel layer 132 may be positioned on both sides of the gate electrode 155 to be spaced apart from each other. The source electrode 173 and the drain electrode 175 may be positioned within the trench positioned on both sides of the gate electrode 155, respectively. The source electrode 173 and the drain electrode 175 may be formed to fill the trench. Within the trench, the source electrode 173 and the drain electrode 175 may be in contact with the channel layer 132 and the barrier layer 136. The channel layer 132 may define the bottom surface and sidewall of the trench, and the barrier layer 136 may define the sidewall of the trench. Accordingly, the source electrode 173 and the drain electrode 175 may contact the upper and side surfaces of the channel layer 132. Additionally, the source electrode 173 and the drain electrode 175 may be in contact with the side of the barrier layer 136. That is, the source electrode 173 and the drain electrode 175 may cover the sides of the channel layer 132 and the barrier layer 136.

In an embodiment, the source electrode 173 and the drain electrode 175 may cover at least a portion of the side of the protection layer 500. For example, the source electrode 173 and the drain electrode 175 may cover the side of the first protection layer 510 and the side of the second protection layer 520. The upper surface of the source electrode 173 and the drain electrode 175 may protrude from the upper surface of the protection layer 500. Additionally, at least one from among the source electrode 173 and the drain electrode 175 may cover at least a portion of the upper surface of the protection layer 500. However, embodiments of the present disclosure are not limited thereto. For example, the source electrode 173 and the drain electrode 175 may cover at least part of the side of the protection layer 500 and may not cover the remaining part of the side of the protection layer 500. In this case, the remaining part of the protection layer 500 may be positioned on the upper surfaces of the source electrode 173 and the drain electrode 175. This is described later with reference to FIG. 8.

The source electrode 173 and the drain electrode 175 may include a conductive material. For example, the source electrode 173 and the drain electrode 175 may include a metal, a metal alloy, a conductive metal nitride, a metal silicide, a doped semiconductor material, a conductive metal oxide, or a conductive metal oxynitride. For example, the source electrode 173 and the drain electrode 175 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonizationnitride (TiAlC-N), titanium aluminum carbide (TiAlC), titanium carbide (TiC), tantalum carbonizationnitride (TaCN), tungsten (W), aluminum (AI), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combination thereof, but embodiments of the present disclosure are not limited thereto. The source electrode 173 and the drain electrode 175 may be made of a single layer or multiple layers. The source electrode 173 and the drain electrode 175 may be in ohmic contact with the channel layer 132. The region in contact with the source electrode 173 and the drain electrode 175 within the channel layer 132 may be doped at a relatively high concentration compared to other regions of the channel layer 132.

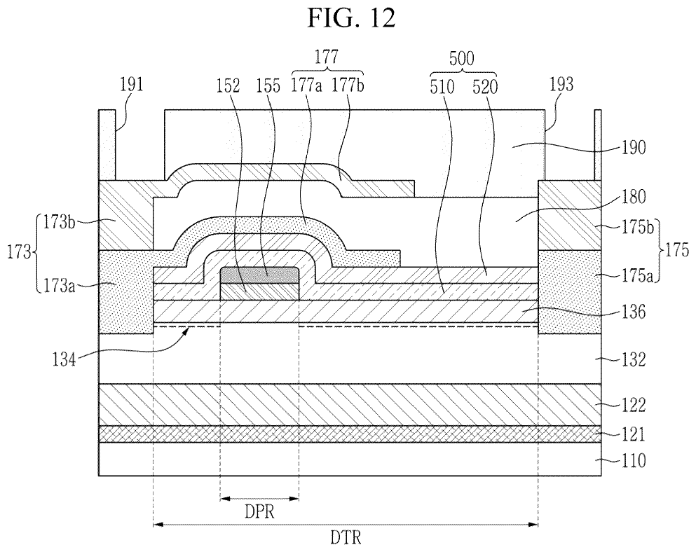

In FIG. 1 and FIG. 2, it is shown that the semiconductor device according to an embodiment includes a pair of the source electrode 173 and the drain electrode 175, but the number of the source electrode 173 and the drain electrode 175 is not limited thereto. For example, the source electrode 173 may include a first source electrode 173a (see FIG. 12) and a second source electrode 173b (see FIG. 12) sequentially stacked on the channel layer 132, and the drain electrode 175 may include a first drain electrode 175a (see FIG. 12) and a second drain electrode 175b (see FIG. 12) sequentially stacked on the channel layer 132. Alternatively, each of the source electrode 173 and the drain electrode 175 may include three or more layers.

The field dispersion layer 177 may be positioned between the source electrode 173 and the drain electrode 175. The field dispersion layer 177 may cover the gate electrode 155. The field dispersion layer 177 may overlap with the gate electrode 155 in the vertical direction (e.g., the thickness direction of the channel layer 132). The field dispersion layer 177 may be electrically connected to the source electrode 173. For example, the field dispersion layer 177 may be connected to the source electrode 173.

In an embodiment, the field dispersion layer 177 may include the same material as a material of the source electrode 173 and may be positioned in the same layer as the source electrode 173. The field dispersion layer 177 may be formed simultaneously in the same process as the source electrode 173. That is, the boundary between the field dispersion layer 177 and the source electrode 173 may not be perceptible, and the field dispersion layer 177 may be formed integrally with the source electrode 173. However, embodiments of the present disclosure are not limited to this, and the field dispersion layer 177 may be a separate component from the source electrode 173. Additionally, the field dispersion layer 177 may be positioned in a different layer from the source electrode 173 and may be formed in a different process. In some cases, the field dispersion layer 177 may be electrically connected to the gate electrode 155. For example, an opening that overlaps the gate electrode 155 in the vertical direction may be formed in the protection layer 500, and the field dispersion layer 177 may be connected to the gate electrode 155 through the opening. In such case, the field dispersion layer 177 may not be connected to the source electrode 173.

The field dispersion layer 177 may serve to disperse the electric field concentrated around the gate electrode 155. Specifically, in the gate off state, the portion of the channel layer 132 positioned between the gate electrode 155 and the source electrode 173 and the portion of the channel layer 132 positioned between the gate electrode 155 and the drain electrode 175 include a very high concentration level of the two-dimensional electron gas 134. Accordingly, an electric field may be concentrated on the gate electrode 155 or the gate semiconductor layer 152. Meanwhile, the gate electrode 155 and the gate semiconductor layer 152 are vulnerable to an electric field, so when an electric fields is concentrated, a leakage current may increase and a breakdown voltage may decrease. The semiconductor device according to an embodiment includes the field dispersion layer 177 and may disperse the electric field concentrated around the gate electrode 155 or the gate semiconductor layer 152. Accordingly, a leakage current may be reduced and a breakdown voltage may be increased.

Hereinafter, semiconductor devices according to some embodiments are described with reference to FIG. 3 to FIG. 7.

FIG. 3 to FIG. 7 are cross-sectional views showing semiconductor devices according to some embodiments.

FIG. 3 to FIG. 7 illustrate numerous variations of the semiconductor device according to the embodiment shown in FIG. 1. The embodiments shown in FIG. 3 to FIG. 17 have many parts that are the same as the embodiment shown in FIG. 1, and so repeated description thereof may be omitted and differences may be mainly explained. Additionally, the same reference numeral is used for the same component as the previously described embodiment. In the embodiments shown in FIG. 3 to FIG. 7, the shape, the arrangement of the protection layer may be partially different from the previously described embodiment.

As shown in FIG. 3 to FIG. 7, the semiconductor device according to some embodiments includes the channel layer 132, the barrier layer 136 placed on the channel layer 132, the gate electrode 155 placed on the barrier layer 136, the gate semiconductor layer 152 placed between the barrier layer 136 and the gate electrode 155, the source electrode 173 and the drain electrode 175 separated from each other on the channel layer 132, the protection layer 500 placed on the barrier layer 136, and the field dispersion layer 177 placed on the protection layer 500.

The first protection layer 510 of the semiconductor device according to some embodiments may include a first element. For example, when the first protection layer 510 of the semiconductor device according to some embodiments includes silicon oxide (SiOₓ) (1≤x≤4), the first element may be silicon (Si).

Referring to FIG. 3, in some embodiments, the first protection layer 510 may include the first region 510a, the second region 510b, and the third region 510c with the different ratios of the first element from each other.

The first region 510a, the second region 510b, and the third region 510c of the first protection layer 510 may be positioned sequentially on the upper surface of the barrier layer 136. For example, the first region 510a of the first protection layer 510 may be positioned on the upper surface of the barrier layer 136. The second region 510b of the first protection layer 510 may be positioned on the first region 510a of the first protection layer 510. The third region 510c of the first protection layer 510 may be positioned on the second region 510b of the first protection layer 510. The first region 510a, the second region 510b, and the third region 510c of the first protection layer 510 may be positioned between the barrier layer 136 and the field dispersion layer 177. The first region 510a of the first protection layer 510 may be in contact with the barrier layer 136, and the third region 510c of the first protection layer 510 may be in contact with the second protection layer 520.

In some embodiments, the ratio of the first element of the first protection layer 510 may increase in direction away from the upper surface of the barrier layer 136. For example, the ratio of the first element in the first region 510a of the first protection layer 510 may be smaller than the ratio of the first element in the second region 510b of the first protection layer 510 or the ratio of the first element in the third region 510c of the first protection layer 510. Additionally, the ratio of the first element in the third region 510c of the first protection layer 510 may be greater than the ratio of the first element in the first region 510a of the first protection layer 510 or the ratio of the first element in the second region 510b of the first protection layer 510. For example, the ratio of the first element in the first region 510a of the first protection layer 510 may be smaller than the ratio of the first element in the second region 510b of the first protection layer 510, and the ratio of the first element in the second region 510b of the first protection layer 510 may be smaller than the ratio of the first element in the third region 510c of the first protection layer 510. In other words, the ratio of the first element of the portion of the first protection layer 510 adjacent to the barrier layer 136 may be smaller than the ratio of the first element of the portion of the first protection layer 510 adjacent to the second protection layer 520.

Here, the ratio of the first element in the first region 510a, the second region 510b, and the third region 510c of the first protection layer 510 means the fraction of the first element to the material constituting the first protection layer 510 in the first region 510a, the second region 510b, and the third region 510c. For example, the fraction of the first element may mean a mass percentage (wt %), a mole percentage (mol %), an atom percentage (at %), etc.

For example, the first region 510a of the first protection layer 510 may include silicon oxide (SiOₓ₁, 1≤x1≤4), the second region 510b of the first protection layer 510 may include silicon oxide (SiOₓ₂, 1≤x2≤4), and the third region 510c of the first protection layer 510 may include silicon oxide (SiOₓ₃, 1≤x3≤4). Here, the first element may be silicon (Si), and x1 may be larger than x3. In other words, the ratio of oxygen atoms combining with a unit number of silicon (Si) in the first region 510a of the first protection layer 510 is higher (e.g., much higher) than the ratio of oxygen atoms combining with a unit number of silicon (Si) in the third region 510c of the first protection layer 510. This may mean that the ratio of the first element in the first region 510a of the first protection layer 510 may be smaller than the ratio of the first element in the third region 510c of the first protection layer 510. Additionally, x1 may be larger than x2. In other words, the ratio of oxygen atoms combining with silicon (Si) of unit number in the first region 510a of the first protection layer 510 is higher than the ratio of oxygen atoms combining with silicon (Si) of unit number in second region 510b of the first protection layer 510. This may mean that the ratio of the first element in the first region 510a of the first protection layer 510 may be smaller than the ratio of the first element in the second region 510b of the first protection layer 510.

In the semiconductor device according to an embodiment, if the ratio of the first element of the first protection layer 510 increases as the distance from the upper surface of the barrier layer 136 increases, it is possible to minimize the decrease in hole concentration due to a deactivation that occurs when being combined with the doped impurity (e.g., magnesium) within the gate semiconductor layer 152. Accordingly, the hole concentration of the gate semiconductor layer 152 may be maintained high and the charge may be concentrated within the drift region DTR. In other words, the semiconductor device according to an embodiment may have stable electric characteristics and the reliability may be improved.

In some embodiments, the ratio of the first element within the first region 510a of the first protection layer 510 may increase in a direction away from the upper surface of the barrier layer 136, the ratio of the first element within the second region 510b may increase in the direction away from the upper surface of the barrier layer 136, and the ratio of the first element within the third region 510c may increase in the direction away from the upper surface of the barrier layer 136, but embodiments of the present disclosure are not limited thereto. For example, the ratio of the first element within the first region 510a of the first protection layer 510 may be constant. Additionally, the ratio of the first element within the second region 510b of the first protection layer 510 may be constant. Additionally, the ratio of the first element within the third region 510c of the first protection layer 510 may be constant. However, even in this case, the ratio of the first element in the first region 510a of the first protection layer 510 may be the smallest, and the ratio of the first element in the third region 510c of the first protection layer 510 may be the largest.

With respect to some embodiments, the first protection layer 510 is described as including three regions, but is not limited thereto. For example, the first protection layer 510 may include two regions with different ratios of the first element positioned sequentially from the upper surface of the barrier layer 136. As another example, the first protection layer 510 may include four or more regions with different ratios of the first element positioned sequentially from the upper surface of the barrier layer 136.

Referring to FIG. 4, the first protection layer 510 of the semiconductor device according to some embodiments may include a first lower protection layer 511, a second lower protection layer 512, and a third lower protection layer 513 sequentially positioned from the upper surface of the barrier layer 136.

The first lower protection layer 511, the second lower protection layer 512, and the third lower protection layer 513 may be positioned sequentially from the upper surface of the barrier layer 136. For example, the first lower protection layer 511 may be positioned on the upper surface of barrier layer 136. The second lower protection layer 512 may be positioned on the first lower protection layer 511. The third lower protection layer 513 may be positioned on the second lower protection layer 512. The first lower protection layer 511, the second lower protection layer 512, and the third lower protection layer 513 may be positioned between the barrier layer 136 and the field dispersion layer 177. The first lower protection layer 511 may be in contact with the barrier layer 136, and the third lower protection layer 513 may be in contact with the second protection layer 520.

In some embodiments, the first lower protection layer 511, the second lower protection layer 512, and the third lower protection layer 513 may include an insulating material. At least one from among the first lower protection layer 511, the second lower protection layer 512, and the third lower protection layer 513 may include different materials, but is not limited thereto. For example, the first lower protection layer 511, the second lower protection layer 512, and the third lower protection layer 513 may include material such as silicon oxide (SiOₓ) (1≤x≤4), silicon nitride (SiN), silicon oxynitride (SiON), aluminum oxide (Al₂O₃), and the like. According to embodiments, at least one from among the first lower protection layer 511, the second lower protection layer 512, and the third lower protection layer 513 may include the first element. For example, the first element may include silicon (Si).

In some embodiments, the ratio of at least one first element of the first lower protection layer 511, the second lower protection layer 512, and the third lower protection layer 513 may be different. As an example, if the first lower protection layer 511, the second lower protection layer 512, and the third lower protection layer 513 all include the first element, the ratio of the first element of the first lower protection layer 511 may be less than or equal to the ratio of the first element of the second lower protection layer 512. Alternatively, the ratio of the first element of the second lower protection layer 512 may be less than or equal to the ratio of the first element of the third lower protection layer 513. As another example, if the first lower protection layer 511 and the third lower protection layer 513 include the first element, and the second lower protection layer 512 does not include the first element, the ratio of the first element of the first lower protection layer 511 may be less than or equal to the ratio of the first element of the third lower protection layer 513. In other words, the ratio of the first element of the portion of the first protection layer 510 adjacent to the barrier layer 136 may be smaller than the ratio of the first element of the portion of the first protection layer 510 adjacent to the second protection layer 520. However, this is only an example embodiment, and the ratio of the first element of the first lower protection layer 511, the second lower protection layer 512, and the third lower protection layer 513 may vary within a range that increases in a direction away from the upper surface of the barrier layer 136.

Here, the ratio of the first element of the first lower protection layer 511, the second lower protection layer 512, and the third lower protection layer 513 may mean the fraction of the first element to the material constituting the first lower protection layer 511, the second lower protection layer 512, and the third lower protection layer 513. For example, the fraction of the first element may mean a mass percentage (wt %), a mole percentage (mol %), an atom percentage (at %), etc.

In some embodiments, the ratio of the first element within the first lower protection layer 511 may increase in a direction away from the upper surface of the barrier layer 136, the ratio of the first element within the second lower protection layer 512 may increase in the direction away from the upper surface of the barrier layer 136, and the ratio of the first element within the third lower protection layer 513 may increase in the direction away from the upper surface of the barrier layer 136, but embodiments of the present disclosure are not limited thereto. For example, the ratio of the first element within the first lower protection layer 511 may be constant. Additionally, the ratio of the first element within the second lower protection layer 512 may be constant. Additionally, the ratio of the first element within the third lower protection layer 513 may be constant. However, even in this case, the ratio of the first element in the first lower protection layer 511 may be the smallest, and the ratio of the first element in the third lower protection layer 513 may be the largest.

With respect to some embodiments, the first protection layer 510 is described as including three lower protection layers, but is not limited thereto. For example, the first protection layer 510 may include two lower protection layers positioned sequentially from the upper surface of the barrier layer 136 and having different first element ratios. As another example, the first protection layer 510 may include four or more lower protection layers positioned sequentially from the upper surface of the barrier layer 136 and having different first element ratios.

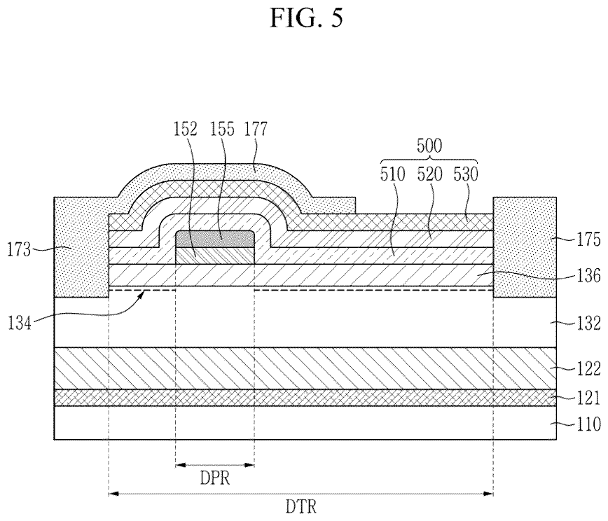

Referring to FIG. 5, the semiconductor device according to some embodiments may further include a third protection layer 530 positioned above the second protection layer 520.

The third protection layer 530 may be positioned on the second protection layer 520. The third protection layer 530 may cover the second protection layer 520. For example, the third protection layer 530 may be positioned on the second protection layer 520 between the source electrode 173 and the drain electrode 175. The third protection layer 530 may overlap the drift region DTR of channel layer 132 in the vertical direction (e.g., the thickness direction of channel layer 132). The upper surface of the third protection layer 530 may be in contact with the lower surface of the field dispersion layer 177. The third protection layer 530 may be not in contact with the gate electrode 155 and the gate semiconductor layer 152, but embodiments of the present disclosure are not limited thereto. The lower surface of the third protection layer 530 may be in contact with the second protection layer 520. The side of the third protection layer 530 may be in contact with the source electrode 173 and the drain electrode 175. However, embodiments of the present disclosure are not limited thereto, and the third protection layer 530 may cover the upper surfaces of the source electrode 173 and the drain electrode 175.

In some embodiments, the third protection layer 530 may be positioned between the second protection layer 520 and the field dispersion layer 177. At least a portion of the third protection layer 530 may overlap with the field dispersion layer 177 in the vertical direction (e.g., the thickness direction of the channel layer 132).

In some embodiments, the third protection layer 530 may include an insulating material. The third protection layer 530 may include a material different than a material of the second protection layer 520. Additionally, the third protection layer 530 may include the same material as the first protection layer 510, but is not limited thereto. For example, the third protection layer 530 may include silicon oxide (SiOₓ) (1≤x≤4). Alternatively, the third protection layer 530 may include materials such as silicon nitride (SiN), aluminum oxide (Al₂O₃), etc.

In some embodiments, the third protection layer 530 may include the first element. For example, when the third protection layer 530 of a semiconductor device according to an embodiment includes silicon oxide (SiOₓ) (1≤x≤4), the first element may be silicon (Si). The ratio of the first element of the third protection layer 530 may increase in a direction away from the upper surface of the barrier layer 136, but embodiments of the present disclosure are not limited thereto. Additionally, the ratio of the first element of the third protection layer 530 may be greater than or equal to the ratio of the first element of the first protection layer 510.

With respect to some embodiments, the first element included in the third protection layer 530 is explained as silicon (Si), but embodiments of the present disclosure are not limited thereto. The first element may vary depending on the material included in the third protection layer 530.

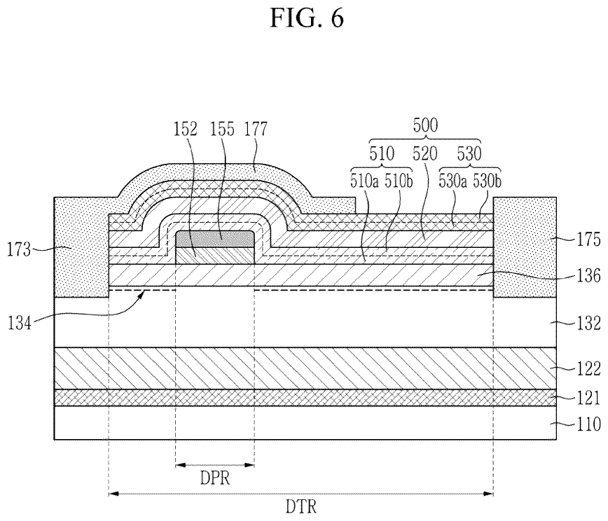

Referring to FIG. 6, in some embodiments, the first protection layer 510 may include the first region 510a and the second region 510b with different first element ratios from each other, and the third protection layer 530 may include a first region 530a and the second region 530b with different first element ratios from each other.

The first region 510a and the second region 510b of the first protection layer 510 may be positioned sequentially from the upper surface of the barrier layer 136. In an embodiment, the ratio of the first element of the first protection layer 510 may increase in a direction away from the upper surface of the barrier layer 136. For example, the ratio of the first element in the first region 510a of the first protection layer 510 may be smaller than the ratio of the first element in the second region 510b of the first protection layer 510. Other aspects of the first region 510a and the second region 510b of the first protection layer 510 may be substantially the same as aspects of the first protection layer 510 described with reference to the embodiment shown in FIG. 3, and so repeated description thereof is omitted.

The first region 530a and the second region 530b of the third protection layer 530 may be positioned sequentially from the upper surface of the barrier layer 136. For example, the first region 530a of the third protection layer 530 may be positioned on the upper surface of the barrier layer 136. The second region 530b of the third protection layer 530 may be positioned on the first region 530a of the third protection layer 530. The first region 530a and the second region 530b of the third protection layer 530 may be positioned between the second protection layer 520 and the field dispersion layer 177. The first region 530a of the third protection layer 530 may be in contact with the second protection layer 520, and the second region 530b of the third protection layer 530 may be in contact with the field dispersion layer 177.

In some embodiments, the ratio of the first element of the third protection layer 530 may increase in a direction away from the upper surface of the barrier layer 136. For example, the ratio of the first element in the first region 530a of the third protection layer 530 may be smaller than the ratio of the first element in the second region 530b of the third protection layer 530. In other words, the ratio of the first element of the portion of the third protection layer 530 adjacent to the second protection layer 520 may be smaller than the ratio of the first element of the portion of the third protection layer 530 adjacent to the field dispersion layer 177.

Here, the ratio of the first element in the first region 530a and the second region 530b of the third protection layer 530 may mean the fraction of the first element to the material constituting the third protection layer 530 in the first region 530a and the second region 530b. For example, the fraction of the first element may mean a mass percentage (wt %), a mole percentage (mol %), an atom percentage (at %), etc.

In some embodiments, the ratio of the first element of the third protection layer 530 may be greater than or equal to the ratio of the first element of the first protection layer 510. For example, the ratio of the first element in the first region 530a of the third protection layer 530 may be greater than or equal to the ratio of the first element in the second region 510b of the first protection layer 510. Accordingly, the ratio of the first element in the second region 530b of the third protection layer 530 may be greater than the ratio of the first element in the second region 510b of the first protection layer 510.

In some embodiments, the ratio of the first element within the first region 530a of the third protection layer 530 may increase in a direction away from the upper surface of the barrier layer 136, and the ratio of the first element within the second region 530b may increase in the direction away from the upper surface of the barrier layer 136, but embodiments of the present disclosure are not limited thereto. For example, the ratio of the first element within the first region 530a of the third protection layer 530 may be constant. Additionally, the ratio of the first element within the second region 530b may be constant. However, even in this case, the ratio of the first element in the first region 530a of the third protection layer 530 may be smaller than the ratio of the first element in the second region 530b of the third protection layer 530.

With respect to some embodiments, the third protection layer 530 is described as including two regions, but embodiments of the present disclosure are not limited thereto. For example, the third protection layer 530 may include three or more regions positioned sequentially from the upper surface of the barrier layer 136 and including different first element ratios.

With respect to some embodiments, the first protection layer 510 and the third protection layer 530 are described as including a plurality of regions with different first element ratios, but embodiments of the present disclosure are not limited thereto. For example, at least one from among the first protection layer 510 and the third protection layer 530 may include a plurality of regions in which the ratios of the first element are different.

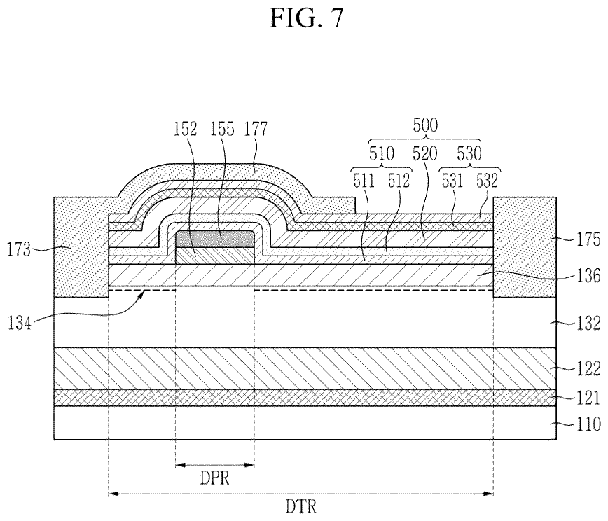

Referring to FIG. 7, the first protection layer 510 of the semiconductor device according to some embodiments may include a first lower protection layer 511 and a second lower protection layer 512 sequentially positioned from the upper surface of the barrier layer 136, and the third protection layer 530 may include a first upper protection layer 531 and a second upper protection layer 532 sequentially positioned from the upper surface of the second protection layer 520.

The first lower protection layer 511 and the second lower protection layer 512 may be positioned sequentially from the upper surface of the barrier layer 136. The first lower protection layer 511 and the second lower protection layer 512 may be positioned between the barrier layer 136 and the second protection layer 520. The first lower protection layer 511 may be in contact with the barrier layer 136, and the second lower protection layer 512 may be in contact with the second protection layer 520. Other aspects of the first lower protection layer 511 and the second lower protection layer 512 may be substantially the same as aspects of the first lower protection layer 511 and the second lower protection layer 512 described with respect to the embodiment shown in FIG. 4, and therefore repeated description thereof may be omitted.

The first upper protection layer 531 and the second upper protection layer 532 may be positioned sequentially from the upper surface of the second protection layer 520. For example, the first upper protection layer 531 may be positioned on the upper surface of the second protection layer 520. The second upper protection layer 532 may be positioned on the first upper protection layer 531. The first upper protection layer 531 and the second upper protection layer 532 may be positioned between the second protection layer 520 and the field dispersion layer 177. The first upper protection layer 531 may be in contact with the second protection layer 520, and the second upper protection layer 532 may be in contact with the field dispersion layer 177.

In some embodiments, the first upper protection layer 531 and the second upper protection layer 532 may include an insulating material. The first upper protection layer 531 and the second upper protection layer 532 may include different materials or the same material as each other. For example, the first upper protection layer 531 and the second upper protection layer 532 may include at least one material such as silicon oxide (SiOₓ) (1≤x≤4), silicon nitride (SiN), silicon oxynitride (SiON), aluminum oxide (Al₂O₃). At least one from among the first upper protection layer 531 and the second upper protection layer 532 may include a first element. For example, the first element may include silicon (Si).

In some embodiments, when the first upper protection layer 531 and the second upper protection layer 532 both include the first element, the ratio of the first element of the first upper protection layer 531 may be less than or equal to the ratio of the first element of the second upper protection layer 532. In other words, the ratio of the first element of the portion of the third protection layer 530 adjacent to the second protection layer 520 may be smaller than the ratio of the first element of the portion of the third protection layer 530 adjacent to the field dispersion layer 177.

Additionally, the ratio of the first element of the third protection layer 530 may be greater than or equal to the ratio of the first element of the first protection layer 510. For example, the ratio of the first element of the first upper protection layer 531 may be greater than or equal to the ratio of the first element of the second lower protection layer 512. Accordingly, the ratio of the first element of the second upper protection layer 532 may be greater than or equal to the ratio of the first element of the second upper protection layer 532. Here, the ratio of the first element of the first upper protection layer 531 and the second upper protection layer 532 may mean the fraction of the first element to the material constituting the first upper protection layer 531 and the second upper protection layer 532. For example, the fraction of the first element may mean a mass percentage (wt %), a mole percentage (mol %), an atom percentage (at %), etc.

In some embodiments, the ratio of the first element within the first upper protection layer 531 may increase in a direction away from the upper surface of the barrier layer 136, and the ratio of the first element within the second upper protection layer 532 may increase in the direction away from the upper surface of the barrier layer 136, but embodiments of the present disclosure are not limited thereto. For example, the ratio of the first element within the first upper protection layer 531 may be constant. Additionally, the ratio of the first element within the second upper protection layer 532 may be constant. However, even in this case, the ratio of the first element of the first upper protection layer 531 may be less than or equal to the ratio of the first element of the second upper protection layer 532.

With respect to some embodiments, the first protection layer 510 is described as including the first lower protection layer 511 and the second lower protection layer 512, and the third protection layer 530 is described as including the first upper protection layer 531 and the second upper protection layer 532, but embodiments of the present disclosure are not limited thereto. For example, at least one from among the first protection layer 510 and the third protection layer 530 may include three or more layers.

Hereinafter, the semiconductor device according to embodiments is described with reference to FIG. 8 to FIG. 11.

FIG. 8 to FIG. 11 are cross-sectional views showing a semiconductor device according to some embodiments.

FIG. 8 to FIG. 11 show numerous variations of the semiconductor device according to the embodiment shown in FIG. 1. The embodiments shown in FIG. 8 to FIG. 11 include many parts that are the same as the embodiments shown in FIGS. 1-7, and so repeated description thereof may be omitted and the differences may be mainly explained. Additionally, the same reference numerals are used for the same components as the previously described embodiments. In the embodiments shown in FIG. 8 to FIG. 11, the shape and/or the arrangement, and the like of the protection layer may be partially different from the previously described embodiments.

As shown in FIG. 8 to FIG. 11, the semiconductor device according to some embodiments includes the channel layer 132, the barrier layer 136 positioned on the channel layer 132, the gate electrode 155 positioned on the barrier layer 136, the gate semiconductor layer 152 positioned between the barrier layer 136 and the gate electrode 155, the source electrode 173 and the drain electrode 175 separated from each other on the channel layer 132, the protection layer 500 positioned on the barrier layer 136, and the field dispersion layer 177 positioned on the protection layer 500.

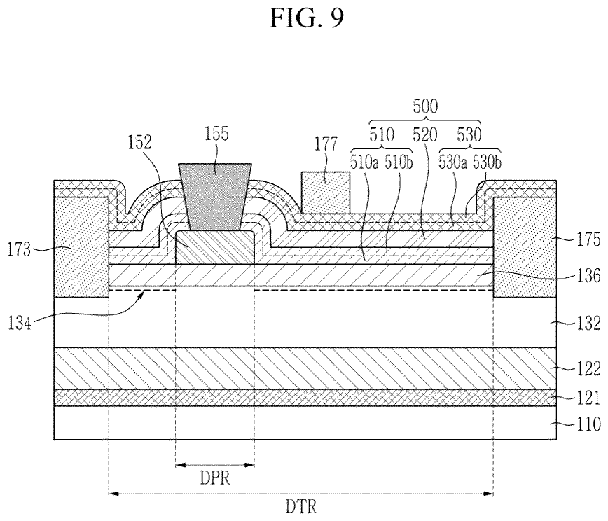

Referring to FIG. 8 and FIG. 9, the gate electrode 155 of a semiconductor device according to some embodiments may be connected to the gate semiconductor layer 152 through the protection layer 500.

In some embodiments, the gate electrode 155 may penetrate the protection layer 500. For example, the gate electrode 155 may penetrate the first protection layer 510, the second protection layer 520, and the third protection layer 530 on the gate semiconductor layer 152. Accordingly, at least a portion of the side of the gate electrode 155 may be in contact with the protection layer 500. The gate electrode 155 may overlap with the gate semiconductor layer 152 in the vertical direction (e.g., the thickness direction of the channel layer 132). The lower surface of the gate electrode 155 may be in contact with the upper surface of the gate semiconductor layer 152. The gate electrode 155 may be positioned on at least a portion of the gate semiconductor layer 152. For example, as shown in FIG. 8 and FIG. 9, the gate electrode 155 may be positioned on a portion of the gate semiconductor layer 152, and the first protection layer 510 may be positioned on the remaining portion of the gate semiconductor layer 152. That is, the upper surface of the gate semiconductor layer 152 may be in contact with the gate electrode 155 and the first protection layer 510. However, embodiments of the present disclosure are not limited thereto, and the gate semiconductor layer 152 may completely overlap with the gate electrode 155.

In some embodiments, the protection layer 500 may cover at least a portion of the barrier layer 136 and the gate semiconductor layer 152. Additionally, the field dispersion layer 177 may be positioned on the protection layer 500. For example, the field dispersion layer 177 may be positioned between the gate electrode 155 and the drain electrode 175. According to embodiments, the field dispersion layer 177 may be connected to the gate electrode 155 or the source electrode 173. However, embodiments of the present disclosure are not limited thereto, and the field dispersion layer 177 may not be connected to the gate electrode 155 and the source electrode 173. Additionally, the field dispersion layer 177 may extend in one direction. For example, the field dispersion layer 177 may extend in a direction parallel to the gate electrode 155, the source electrode 173, and the gate electrode 155. That is, the field dispersion layer 177 may extend parallel to the gate electrode 155, the source electrode 173, and the gate electrode 155.

The protection layer 500 of the semiconductor device according to some embodiments may include a first protection layer 510, a second protection layer 520, and a third protection layer 530 sequentially stacked from the upper surface of the barrier layer 136.

The first protection layer 510, the second protection layer 520, and the third protection layer 530 may be penetrated by the gate electrode 155. The first protection layer 510, the second protection layer 520, and the third protection layer 530 may surround at least part of the side of gate electrode 155. The sides of the first protection layer 510, the second protection layer 520, and the third protection layer 530 may be in contact with gate electrode 155. The first protection layer 510 may surround the gate semiconductor layer 152. The first protection layer 510 may surround the side of the gate semiconductor layer 152. The first protection layer 510 may surround at least a portion of the upper surface of the gate semiconductor layer 152, but embodiments of the present disclosure are not limited thereto.

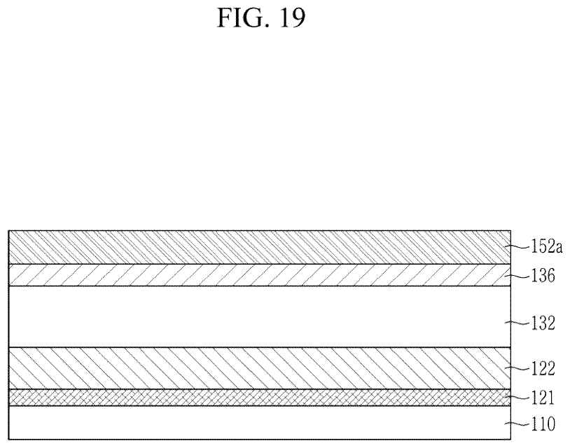

In some embodiments, the third protection layer 530 may be positioned on the source electrode 173 and the drain electrode 175. For example, the third protection layer 530 may be positioned on the second protection layer 520, the source electrode 173, and the drain electrode 175. Accordingly, the third protection layer 530 may cover the upper and side surfaces of the source electrode 173 and the upper and side surfaces of the drain electrode 175. The source electrode 173 and the drain electrode 175 may be covered by the first protection layer 510, the second protection layer 520, and the third protection layer 530. This may be due to the process characteristic of forming the third protection layer 530 after forming the first protection layer 510 and the second protection layer 520, and forming the source electrode 173 and the drain electrode 175. This is described with reference to FIG. 19 to FIG. 24 later.

The first protection layer 510, the second protection layer 520, and the third protection layer 530 of the semiconductor device according to some embodiments may include an insulating material. The first protection layer 510 and the third protection layer 530 may include materials different than a material of the second protection layer 520. The first protection layer 510 and the third protection layer 530 may include the first element. For example, the first element may be silicon (Si). The ratio of the first element of the first protection layer 510 may be less than or equal to the ratio of the first element of the third protection layer 530. For example, as shown in FIG. 8, if the first protection layer 510 and the third protection layer 530 are composed of a single layer with the constant ratio of the first element, the ratio of the first element of the first protection layer 510 may be less than or equal to the ratio of the first element of the third protection layer 530. As another example, as shown in FIG. 9, when the first protection layer 510 includes the first region 510a and the second region 510b sequentially positioned from the upper surface of the barrier layer 136, and the third protection layer 530 includes the first region 530a and the second region 530b sequentially positioned from the upper surface of the second protection layer 520, the ratio of the first element in the second region 510b of the first protection layer 510 may be less than or equal to the ratio of the first element in the first region 530a of the third protection layer 530. Additionally, the ratio of the first element in the first region 510a of the first protection layer 510 may be less than or equal to the ratio of the first element in the second region 510b of the first protection layer 510. The ratio of the first element in the first region 530a of the third protection layer 530 may be less than or equal to the ratio of the first element in the second region 530b of the third protection layer 530.

With reference to FIG. 9, the first protection layer 510 and the third protection layer 530 were explained as including two regions, but embodiments of the present disclosure are not limited thereto. For example, the first protection layer 510 and the third protection layer 530 may each include three or more regions positioned sequentially from the upper surface of the barrier layer 136 and having the first element of the different ratios.

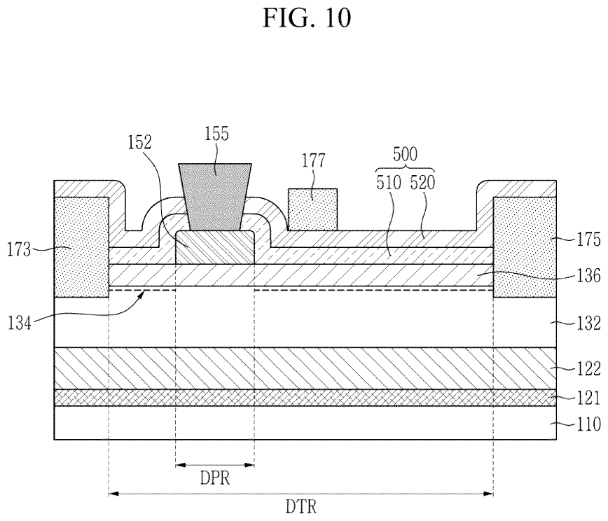

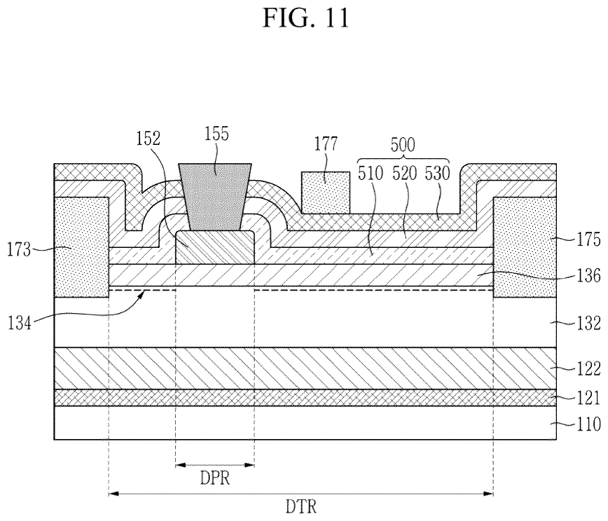

Referring to FIG. 10 and FIG. 11, the protection layer 500 according to some embodiments may be further positioned above the source electrode 173 and the drain electrode 175.

For example, as shown in FIG. 10, the second protection layer 520 may be positioned above the first protection layer 510, the source electrode 173, and the drain electrode 175. Accordingly, the second protection layer 520 may cover the upper and side surfaces of the source electrode 173 and the upper and side surfaces of the drain electrode 175. The source electrode 173 and the drain electrode 175 may be covered by the first protection layer 510, the second protection layer 520, and the third protection layer 530. As another example, as shown in FIG. 11, the second protection layer 520 may be positioned on the source electrode 173 and the drain electrode 175, and the third protection layer 530 may be positioned on the second protection layer 520. The third protection layer 530 may be positioned on the source electrode 173 and the drain electrode 175. This may be due to the process characteristic of forming the first protection layer 510, forming the source electrode 173 and the drain electrode 175, and then forming the second protection layer 520.

In FIG. 10 and FIG. 11, the first protection layer 510 and the third protection layer 530 are shown as being composed of a single layer, but embodiments of the present disclosure are not limited thereto. For example, the first protection layer 510 and the third protection layer 530 may include a plurality of regions with the first element of the different ratios or may be composed of multiple layers.

Hereinafter, the semiconductor device according to some embodiments is described with reference to FIG. 12.

FIG. 12 is a cross-sectional view showing a semiconductor device according to some embodiments.

FIG. 12 is an example variation of the semiconductor device according to the embodiment shown in FIG. 1. The embodiment shown in FIG. 12 includes many parts that are the same as the embodiment shown in FIG. 1, so that repeated description thereof may be omitted and the differences may be mainly explained. Additionally, the same reference numerals are used for the same components as the previous embodiment. The embodiment shown in FIG. 12 may be slightly different from the previously described embodiments in that it further includes a capping layer and includes a plurality of field dispersion layers.

As shown in FIG. 12, the semiconductor device according to some embodiments includes the channel layer 132, the barrier layer 136 positioned on the channel layer 132, the gate electrode 155 positioned on the barrier layer 136, the gate semiconductor layer 152 positioned between the barrier layer 136 and the gate electrode 155, the source electrode 173 and the drain electrode 175 separated from each other on the channel layer 132, the protection layer 500 positioned on the barrier layer 136, and the field dispersion layer 177 positioned on the protection layer 500.

Each of the source electrode 173, the drain electrode 175, and the field dispersion layer 177 of the semiconductor device according to some embodiments may include a plurality of layers. For example, the source electrode 173 of the semiconductor device according to some embodiments may include a first source electrode 173a and a second source electrode 173b, the drain electrode 175 may include a first drain electrode 175a and a second drain electrode 175b, and the field dispersion layer 177 may include a first field dispersion layer 177a and a second field dispersion layer 177b. Also, the semiconductor device according to some embodiments may further include a middle insulating layer 180 positioned on the barrier layer 136 and the first field dispersion layer 177a, and a capping layer 190 covering the middle insulating layer 180 and the second field dispersion layer 177b.

In some embodiments, the second source electrode 173b may be positioned above the first source electrode 173a. The first source electrode 173a may be in directly contact with the channel layer 132 and be electrically connected to the channel layer 132. The second source electrode 173b may not be in direct contact with the channel layer 132, and may be electrically connected to the channel layer 132 through the first source electrode 173a.

The second drain electrode 175b may be positioned on the first drain electrode 175a. The first drain electrode 175a may be in directly contact with the channel layer 132 and may be electrically connected to the channel layer 132. The second drain electrode 175b may not be in direct contact with the channel layer 132, and may be electrically connected to the channel layer 132 through the first drain electrode 175a.

The second source electrode 173b and the second drain electrode 175b may penetrate the middle insulating layer 180. Specifically, an opening that penetrates the middle insulating layer 180 may be positioned to overlap the first source electrode 173a, and the second source electrode 173b may be positioned within the opening. The second source electrode 173b may be formed to fill the opening. Within the opening, the second source electrode 173b may be in contact with the first source electrode 173a. The second source electrode 173b may be connected to the first source electrode 173a through the opening. Another opening that penetrates the middle insulating layer 180 may be positioned to overlap the first drain electrode 175a, and the second drain electrode 175b may be positioned within the opening. The second drain electrode 175b may be formed to fill the opening. Within the opening, the second drain electrode 175b may be in contact with the first drain electrode 175a. The second drain electrode 175b may be connected to the first drain electrode 175a through opening.

The upper surface of the second source electrode 173b and the second drain electrode 175b may protrude from the upper surface of the middle insulating layer 180. Additionally, at least one from among the second source electrode 173b and the second drain electrode 175b may cover at least a portion of the upper surface of the middle insulating layer 180.

The opening filled with second source electrode 173b may overlap with the trench filled with first source electrode 173a. However, embodiments of the present disclosure are not limited to this, and in some cases, the opening and trench may not overlap. The opening filled with second source electrode 173b may completely overlap with first source electrode 173a. However, embodiments of the present disclosure are not limited to this, and in some cases, at least a portion of the opening filled with the second source electrode 173b may not overlap with the first source electrode 173a. Additionally, the opening filled with second drain electrode 175b may overlap with the trench filled with first drain electrode 175a. However, embodiments of the present disclosure are not limited to this, and in some cases, the opening and the trench may not overlap. The opening filled with second drain electrode 175b may completely overlap with the first drain electrode 175a. However, embodiments of the present disclosure are not limited to this, and in some cases, at least a portion of the opening filled with the second drain electrode 175b may not overlap with the first drain electrode 175a.

The semiconductor device according to an embodiment may further include a second field dispersion layer 177b positioned above the middle insulating layer 180. The second field dispersion layer 177b may be positioned between the source electrode 173 and the drain electrode 175. The second field dispersion layer 177b may overlap with the gate electrode 155. The second field dispersion layer 177b may overlap with the first field dispersion layer 177a. The gate electrode 155 and the first field dispersion layer 177a may be covered by the second field dispersion layer 177b. The second field dispersion layer 177b may be wider than the width of the first field dispersion layer 177a. The second field dispersion layer 177b may entirely cover the first field dispersion layer 177a. However, embodiments of the present disclosure are not limited to this, and the width and the position relationship of the first field dispersion layer 177a and the second field dispersion layer 177b may be changed in various ways. The second field dispersion layer 177b may be electrically connected to the source electrode 173. For example, the second field dispersion layer 177b may be connected to the second source electrode 173b.

The second field dispersion layer 177b may include the same material as a material of the second source electrode 173b and may be positioned in the same layer as the second source electrode 173b. The second field dispersion layer 177b may be formed simultaneously in the same process as the second source electrode 173b. The boundary between the second field dispersion layer 177b and the second source electrode 173b may not be perceptible, and the second field dispersion layer 177b may be formed integrally with the second source electrode 173b. However, embodiments of the present disclosure are not limited to this, and the second field dispersion layer 177b may be a separate component from the second source electrode 173b. Additionally, the second field dispersion layer 177b may be positioned in a different layer from a layer of the second source electrode 173b and may be formed in a different process. In some cases, the second field dispersion layer 177b may be electrically connected to the gate electrode 155. For example, the first field dispersion layer 177a may be connected to the gate electrode 155 through an opening formed in the protection layer 500, and the second field dispersion layer 177b may be connected to the first field dispersion layer 177a through an opening formed in the middle insulating layer 180.

The semiconductor device according to an embodiment may further include a capping layer 190 positioned on the source electrode 173 and the drain electrode 175. At least a portion of the upper surface and the side surfaces of the second source electrode 173b and the second drain electrode 175b may be covered by the capping layer 190. The second field dispersion layer 177b may be covered by the capping layer 190. The capping layer 190 is intended to protect the semiconductor device according to an embodiment from external stress, such as moisture or oxygen, and may be positioned as an uppermost layer of the semiconductor device. That is, the capping layer 190 may be positioned as the outermost side of the semiconductor device according to an embodiment. The source electrode 173 and drain electrode 175 may be connected to an external wire, and the capping layer 190 may include pad opened parts (e.g., a first pad opened part 191 and a second pad opened part 193) for a connection to the wire. A first pad opened part 191 that overlaps at least a portion of the source electrode 173 may be formed in the capping layer 190. The upper surface of the source electrode 173 may be exposed to the outside by first pad opened part 191. According to embodiments, a wire electrically connected to the source electrode 173 through the first pad opened part 191 may be further formed. A second pad opened part 193 that overlaps at least a portion of the drain electrode 175 may be formed in the capping layer 190. The upper surface of the drain electrode 175 may be exposed to the outside by the second pad opened part 193. According to embodiments, a wire electrically connected to the drain electrode 175 through the second pad opened part 193 may be further formed.

The capping layer 190 may include an insulating material. For example, the capping layer 190 may include a material such as polyimide (PI), SiO₂, SiN, SiON, the lime. The capping layer 190 may be made of a single layer or multiple layers.

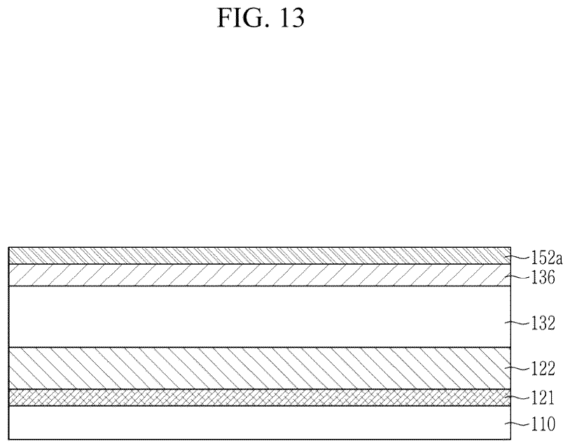

Hereinafter, a method of manufacturing a semiconductor device according to an embodiment is described with reference to FIG. 13 to FIG. 18.

FIG. 13 to FIG. 18 are process cross-sectional views shown according to a process order of manufacturing a semiconductor device according to an embodiment.

First, as shown in FIG. 13, a seed layer 121, a buffer layer 122, a channel layer 132, a barrier layer 136, and a gate semiconductor material layer 152a may be formed sequentially on a substrate 110.

The substrate 110 may include a semiconductor material. For example, the substrate 110 may include sapphire, Si, SiC, AlN, GaN, or combinations thereof. The substrate 110 may be a silicon on insulator (SOI) substrate. However, the material of the substrate 110 is not limited to this, and any generally-used substrate may be applied.

The seed layer 121, buffer layer 122, the channel layer 132, the barrier layer 136, and the gate semiconductor material layer 152a may be formed sequentially using an epitaxial growth method. The seed layer 121 may first be formed on the substrate 110, and the buffer layer 122 may be formed on the seed layer 121. Next, the channel layer 132 may be formed on the buffer layer 122, the barrier layer 136 may be formed on the channel layer 132, and the gate semiconductor material layer 152a may be formed on the barrier layer 136. According to embodiments, the buffer layer 122 may include a supper lattice layer and a high-resistance layer. For example, a supper lattice layer and a high-resistance layer may be formed on the seed layer 121 of the semiconductor device according to an embodiment. In this case, the supper lattice layer and the high-resistance layer may be positioned between the buffer layer 122 and the channel layer 132.

The seed layer 121, the buffer layer 122, the channel layer 132, the barrier layer 136, and the gate semiconductor material layer 152a may be made of the same-based semiconductor material. However, the material composition ratio of each layer may be different considering the role of each layer and the performance required for the semiconductor device. The seed layer 121, buffer layer 122, the channel layer 132, the barrier layer 136, and the gate semiconductor material layer 152a may include one or more material selected from Group Ill-V materials, such as nitrides including Al, Ga, In, B, or a combination thereof. The seed layer, buffer layer 122, the channel layer 132, the barrier layer 136, and the gate semiconductor material layer 152a may be AlₓIn_{y}Ga_{(1-x-y)}N (0≤x≤1, 0≤y≤1, x+y≤1). For example, the seed layer 121, the buffer layer 122, the channel layer 132, the barrier layer 136, and the gate semiconductor material layer 152a may include AlN, GaN, InN, InGaN, AlGaN, AlInN, AlInGaN, or a combination thereof. The barrier layer 136 may include a material having a different energy band gap than the channel layer 132. The barrier layer 136 may have a higher energy band gap than the channel layer 132. The gate semiconductor material layer 152a may include a material having a different energy band gap than the barrier layer 136.

As an example, the substrate 110 may include Si, the seed layer 121 may include AlN, and the buffer layer 122 may include GaN. The channel layer 132 may include GaN, and the barrier layer 136 may include AlGaN. The channel layer 132 and the barrier layer 136 may or may not be impurity doped. The gate semiconductor material layer 152a may include GaN and may be doped with an impurity. The gate semiconductor material layer 152a may be doped with a P-type impurity, for example, magnesium (Mg).

As the lattice structure of Si and the lattice structure of GaN are different, it may not be easy to grow the channel layer 132 made of GaN directly on the substrate 110 made of Si. In the method of manufacturing the semiconductor device according to an embodiment, by first forming the seed layer 121 and the buffer layer 122 on the substrate 110 and then forming the channel layer 132, the lattice structure of the channel layer 132 may be formed stably.

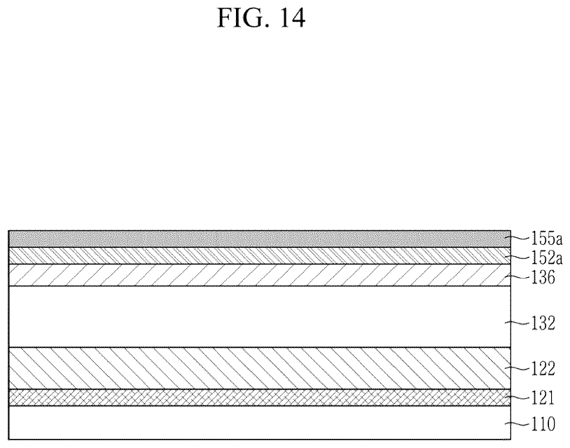

As shown in FIG. 14, the gate electrode material layer 155a may be formed on the gate semiconductor material layer 152a. The gate semiconductor material layer 152a is positioned between the barrier layer 136 and the gate electrode material layer 155a.

The gate electrode material layer 155a may be formed using a deposition process. For example, the gate electrode material layer 155a may be formed using at least one from among a physical vapor deposition (PVD), a thermal chemical vapor deposition (a thermal CVD), a low pressure chemical vapor deposition (LP-CVD), a plasma enhanced chemical vapor deposition (PE-CVD), and an atomic layer deposition (ALD) technologies, but embodiments of the present disclosure are not limited thereto.

The gate electrode material layer 155a may include a conductive material. For example, the gate electrode material layer 155a may include a metal, a metal alloy, a conductive metal nitride, a metal silicide, a doped semiconductor material, a conductive metal oxide, or a conductive metal oxynitride, the like. For example, the gate electrode material layer 155a may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonizationnitride (TiAlC-N), titanium aluminum carbide (TiAlC), titanium carbide (TiC), tantalum carbonizationnitride (TaCN), tungsten (W), aluminum (AI), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combination thereof, but embodiments of the present disclosure are not limited thereto. The gate electrode material layer 155a may be made of a single layer or multiple layers.

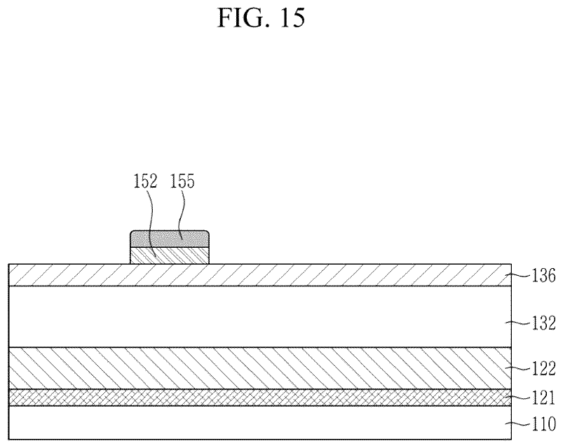

Next, as shown in FIG. 15, by patterning the gate electrode material layer 155a and the gate semiconductor material layer 152a by using a photo and etching process, the gate electrode 155 and the gate semiconductor layer 152 may be formed.

For example, a hard mask layer and a photoresist layer may be formed sequentially on the gate electrode material layer 155a. A photoresist pattern may be formed by patterning the photoresist layer by using a photo process. The hard mask pattern may be formed by etching the hard mask layer using the photoresist pattern as a mask. At least a part of the gate electrode material layer 155a may be removed during the process of etching the hard mask layer. Subsequently, by etching the gate semiconductor material layer 152a by using the hard mask pattern as a mask, at least a portion of the gate semiconductor material layer 152a may be removed. Accordingly, the remaining portion of the gate electrode material layer 155a may become the gate electrode 155. Additionally, the portion of gate semiconductor material layer 152a that remains may become gate semiconductor layer 152. The gate semiconductor layer 152 is positioned between the barrier layer 136 and the gate electrode 155. The gate electrode 155 may be Schottky-contacted or ohmic-contacted to the gate semiconductor layer 152.

By patterning the gate semiconductor material layer 152a and the gate electrode material layer 155a by using the same mask, the gate semiconductor layer 152 and the gate electrode 155 may have the same pattern. That is, the gate semiconductor layer 152 and the gate electrode 155 may have the same planar shape. In the cross-section, the gate semiconductor layer 152 and the gate electrode 155 may have the same width. The gate semiconductor layer 152 may completely overlap with the gate electrode 155 in the vertical direction, and the upper surface of the gate semiconductor layer 152 may be entirely covered by the gate electrode 155, but embodiments of the present disclosure are not limited thereto. For example, the gate semiconductor layer 152 and the gate electrode 155 may partially overlap in the vertical direction.

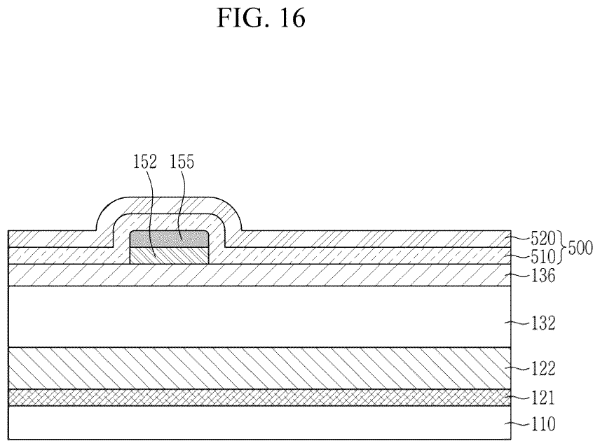

As shown in FIG. 16, a protection layer 500 may be formed on the barrier layer 136 and the gate electrode 155.

For example, a first protection layer 510 and a second protection layer 520 may be formed sequentially on the barrier layer 136 and the gate electrode 155. The first protection layer 510 and the second protection layer 520 may be formed using a deposition process.

In an embodiment, the first protection layer 510 may include an insulating material. For example, the first protection layer 510 may include silicon oxide (SiOₓ) (1≤x≤4). Also, the first protection layer 510 may include a material such as silicon nitride (SiN), aluminum oxide (Al₂O₃), the like.

In an embodiment, the first protection layer 510 may include a first element. For example, when the first protection layer 510 of the semiconductor device according to an embodiment includes silicon oxide (SiOₓ) (1≤x≤4), the first element may be silicon (Si). The first protection layer 510 may include a plurality of regions with different ratios of the first element. For example, the ratio of the first element on the lower part of the first protection layer 510 may be smaller than the ratio of the first element on the upper part of the first protection layer 510. Alternatively, the ratio of the first element of the first protection layer 510 may increase as it moves away from the upper surface of the barrier layer 136. Here, the ratio of the first element of the first protection layer 510 may mean the ratio of the first element for the material constituting the first protection layer 510 in the first region 510a, the second region 510b, and the third region 510c. For example, the fraction of the first element may mean a mass percentage (wt %), a mole percentage (mol %), an atom percentage (at %), etc.

In the semiconductor device according to an embodiment, since the ratio of the first element of the first protection layer 510 increases as the distance from the upper surface of the barrier layer 136 increases, the degree of a doping deactivating may be reduced by the combining with a doped impurity (e.g., magnesium) in the gate semiconductor layer 152. Accordingly, the hole concentration of the gate semiconductor layer 152 may be maintained high and the charge can be concentrated within the drift region DTR. In other words, the semiconductor device according to an embodiment may have stable electric characteristics and the reliability may be improved.

In an embodiment, the second protection layer 520 may include an insulating material. The second protection layer 520 may include a different material than the first protection layer 510. For example, the second protection layer 520 may include silicon oxynitride (SiON), but embodiments of the present disclosure are not limited thereto. For example, the second protection layer 520 may include a first element and a second element different from the first element. For example, when the second protection layer 520 of the semiconductor device according to an embodiment includes silicon oxynitride (SiON), the first element may be silicon (Si) and the second element may be nitrogen (N).

The first protection layer 510 and the second protection layer 520 are shown as a single layer, but may be comprised of multiple layers in some cases. The first protection layer 510 may be formed by sequentially depositing different materials. Alternatively, by varying the deposition conditions using the same material, the first protection layer 510 and the second protection layer 520 consisting of several layers with different characteristics may be formed.

The sides of the gate electrode 155 and the gate semiconductor layer 152 may be covered by the first protection layer 510 and the second protection layer 520. The side of the gate electrode 155 and the gate semiconductor layer 152 may be in contact with the first protection layer 510. A step may occur between the portion of the first protection layer 510 that overlaps with the gate electrode 155 and the gate semiconductor layer 152 and the remaining portion. Additionally, a step may occur between the portion of the second protection layer 520 that overlaps the gate electrode 155 and the gate semiconductor layer 152 and the remaining portion. However, embodiments of the present disclosure are not limited to this, and in some cases, the upper surface of the first protection layer 510 and the upper surface of the second protection layer 520 may be entirely flat. For example, when the thickness of the first protection layer 510 is relatively thick, there may not be a step difference between the part of the first protection layer 510 that overlaps with the gate electrode 155 and the gate semiconductor layer 152 and the remaining part, and between the part of the second protection layer 520 that overlaps with the gate electrode 155 and the gate semiconductor layer 152 and the remaining part.

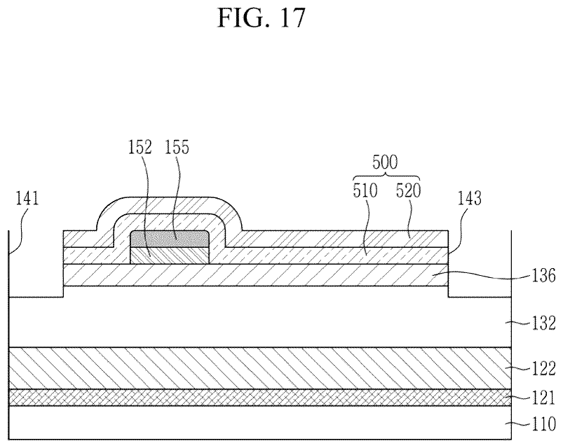

As shown in FIG. 17, the first trench 141 and the second trench 143 may be formed by patterning the protection layer 500 by using a photo and etching processes. In such case, not only the protection layer 500 but also the barrier layer 136 and channel layer 132 may be patterned together.

For example, a photoresist pattern may be formed on the second protection layer 520, and the second protection layer 520, the first protection layer 510, the barrier layer 136, and the channel layer 132 may be sequentially etched using this as a mask. In such case, the second protection layer 520, the first protection layer 510, and the barrier layer 136 may be penetrated by the first trench 141 and the second trench 143, and the upper surface of the channel layer 132 may be recessed. The channel layer 132 may not be penetrated by the first trench 141 or the second trench 143. That is, the depth at which the upper surface of the channel layer 132 is recessed may be smaller than the entire thickness of the channel layer 132. In such case, the depth at which the upper surface of the channel layer 132 is recessed may be much smaller than the entire thickness of the channel layer 132. Additionally, the depth at which the upper surface of the channel layer 132 is recessed may be smaller than the thickness of the barrier layer 136. However, embodiments of the present disclosure are not limited to this, and the depth at which the upper surface of the channel layer 132 is recessed may be changed in various ways.

Due to the first trench 141 and the second trench 143, the sides of the second protection layer 520, the first protection layer 510, and the barrier layer 136 may be exposed to the outside, and the upper and side surfaces of the channel layer 132 may be exposed. The channel layer 132 may form the bottom surface and sidewall of the first trench 141 and the second trench 143, and the barrier layer 136 may form the sidewall of the first trench 141 and the second trench 143.

The first trench 141 and the second trench 143 may be spaced apart from each other. The first trench 141 and the second trench 143 may be positioned on both sides of the gate electrode 155. The first trench 141 may be positioned on one side of the gate electrode 155 to be spaced apart from the gate electrode 155. The second trench 143 may be positioned on the other side of the gate electrode 155 to be spaced apart from the gate electrode 155. The distance that the first trench 141 is separated from the gate electrode 155 may be smaller than the distance that the second trench 143 is separated from the gate electrode 155. The shapes, including the width and the depth, of the first trench 141 and the second trench 143 are shown to be similar, but they are not limited thereto. The shapes of the first trench 141 and the second trench 143 may be changed in various ways.

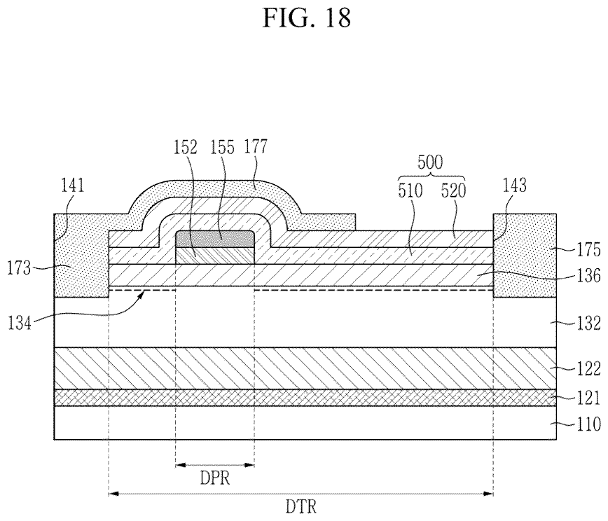

As shown in FIG. 18, a conductive material may be deposited in the first trench 141 and the second trench 143 and patterned to form the source electrode 173 and the drain electrode 175.

The source electrode 173 and the drain electrode 175 may include the conductive material. For example, the source electrode 173 and the drain electrode 175 may include a metal, a metal alloy, a conductive metal nitride, a metal silicide, a doped semiconductor material, a conductive metal oxide, or a conductive metal oxynitride. The source electrode 173 and the drain electrode 175 may be made of a single layer or multiple layers. For example, a plurality of conductive layers including different materials may be stacked and then patterned to form the source electrode 173 and the drain electrode 175. In such case, the plurality of conductive layers may be etched simultaneously or sequentially using one mask pattern. For example, the source electrode 173 and the drain electrode 175 may be formed by sequentially stacking Ti, Al, Ti, and TiN and then patterning them. In such case, the thickness of the four conductive layers constituting the source electrode 173 and the drain electrode 175 may be similar or different. For example, a layer made of Al may be relatively thick compared to other layers.

The source electrode 173 may be formed to fill the interior of the first trench 141. Within the first trench 141, the source electrode 173 may be in contact with the channel layer 132 and the barrier layer 136. The source electrode 173 may be in contact with the sides of the channel layer 132 and the barrier layer 136. The source electrode 173 may cover the sides of the channel layer 132 and the barrier layer 136. The source electrode 173 may be electrically connected to the channel layer 132 through the first trench 141. The upper surface of the source electrode 173 may be protruded from the upper surface of the second protection layer 520.

The drain electrode 175 may be formed to fill the interior of the second trench 143. Within the second trench 143, the drain electrode 175 may be in contact with the channel layer 132 and the barrier layer 136. The drain electrode 175 may be in contact with the sides of the channel layer 132 and the barrier layer 136. The drain electrode 175 may cover the sides of the channel layer 132 and the barrier layer 136. The drain electrode 175 may be electrically connected to the channel layer 132 through the second trench 143. The upper surface of the drain electrode 175 may be protruded from the upper surface of the second protection layer 520.

The source electrode 173 and the drain electrode 175 may be in ohmic contact with the channel layer 132. The region in contact with the source electrode 173 and the drain electrode 175 within the channel layer 132 may be doped at a relatively high concentration compared to other regions. For example, the channel layer 132 may be doped by an ion implant process, an annealing process, etc. However, embodiments of the present disclosure are not limited to this, and the doping process of the channel layer 132 may be comprised of various other processes. The doping process of the channel layer 132 may be performed before forming the source electrode 173 and the drain electrode 175. In some cases, the channel layer 132 may not be doped.

Inside the channel layer 132, a two-dimensional electron gas 134 may be formed in a portion adjacent to the barrier layer 136. The two-dimensional electron gas 134 may be positioned at the interface between the channel layer 132 and the barrier layer 136. The two-dimensional electron gas 134 may be positioned in the drift region DTR between the source electrode 173 and the drain electrode 175. A depletion region DPR may be formed within the channel layer 132 by the gate semiconductor layer 152 having a different energy band gap from the barrier layer 136. Accordingly, the semiconductor device according to an embodiment may have a normally off characteristic. That is, the semiconductor device according to an embodiment may be a normally off high electron mobility transistor (HEMT). In the gate off state, the two-dimensional electron gas 134 may be positioned within the drift region DTR excluding the depletion region DPR of the channel layer 132. In the gate-on state, the flow of two-dimensional electron gas 134 continues within the depletion region DPR, allowing the two-dimensional electron gas 134 to be positioned overall within the drift region DTR.

In the step of forming the source electrode 173 and the drain electrode 175, the field dispersion layer 177 may be formed together. The field dispersion layer 177 may be positioned between the source electrode 173 and the drain electrode 175. The field dispersion layer 177 may overlap with the gate electrode 155. The field dispersion layer 177 may be electrically connected to the source electrode 173. The field dispersion layer 177 may be integrated (e.g., formed integrally) with the source electrode 173. The field dispersion layer 177 may include the same material as a material of the source electrode 173 and may be positioned in the same layer as a layer of the source electrode 173.

Accordingly, the first protection layer 510 may be positioned on the barrier layer 136 between the source electrode 173 and the drain electrode 175. The first protection layer 510 may overlap with the drift region DTR of channel layer 132 in the vertical direction (e.g., the thickness direction of channel layer 132).

Additionally, the first protection layer 510 and the second protection layer 520 may be positioned between the barrier layer 136 and the field dispersion layer 177. At least a portion of the first protection layer 510 and the second protection layer 520 may overlap with the field dispersion layer 177 in the vertical direction (e.g., the thickness direction of the channel layer 132). Accordingly, the portion of the first protection layer 510 and the portion of the second protection layer 520 that overlap with the field dispersion layer 177 in the vertical direction (e.g., the thickness direction of the channel layer 132) may cover the gate semiconductor layer 152 and the gate electrode 155. Accordingly, the barrier layer 136, the gate semiconductor layer 152, and the gate electrode 155 may be protected by the protection layer 500.

In one embodiment, it is described that the conductive material is deposited on the second protection layer 520 and patterned to form the source electrode 173 and the drain electrode 175, but embodiments of the present disclosure are not limited thereto. For example, as in the embodiment illustrated in FIG. 5 to FIG. 7, the third protection layer 530 may be formed on the second protection layer 520, and the conductive material may be deposited and patterned on the third protection layer 530 to form the source electrode 173 and the drain electrode 175.

According to the method of manufacturing the semiconductor device according to an embodiment, since the ratio of the first element of the first protection layer 510 increases as the distance from the upper surface of the barrier layer 136 increases, the degree of a doping deactivating may be reduced by the combining with a doped impurity (e.g., magnesium) in the gate semiconductor layer 152. Accordingly, the hole concentration of the gate semiconductor layer 152 may be maintained high and the charge density within the drift region DTR may be increased. In other words, the semiconductor device according to an embodiment may have stable electric characteristics and the reliability may be improved.

Additionally, by forming the second protection layer 520 of the semiconductor device according to an embodiment on the first protection layer 510, the gate semiconductor layer 152 and the second protection layer 520 may not be in contact. Accordingly, it is possible to prevent the hole concentration within the gate semiconductor layer 152 from being reduced during the process of forming the second protection layer 520. In other words, it is possible to prevent a decrease in the density of the two-dimensional electron gas 134 formed within the channel layer 132, and to prevent characteristic degradations such as an on-current and an on-resistance. In addition, the second protection layer 520 may prevent electrons and holes of the semiconductor device from leaking to the outside, and may prevent moisture or oxygen from penetrating into the channel layer 132. In other words, the semiconductor device according to an embodiment may have stable electric characteristics and a reliability may be improved.

Hereinafter, the method of manufacturing the semiconductor device according to another embodiment is described with reference to FIG. 19 to FIG. 23.

The embodiment shown in FIG. 19 to FIG. 23 includes many parts that are the same as the embodiment shown in FIG. 13 to FIG. 18 so that repeated description thereof may be omitted and differences may be mainly described. Additionally, the same reference numeral is used for the same component as the previous embodiment.

As shown in FIG. 19, a seed layer 121, a buffer layer 122, a channel layer 132, a barrier layer 136, and a gate semiconductor material layer 152a may be formed sequentially on a substrate 110. The descriptions for the substrate 110, the seed layer 121, the buffer layer 122, the channel layer 132, the barrier layer 136, and the gate semiconductor material layer 152a are substantially the same as descriptions for the substrate 110, the seed layer 121, the buffer layer 122, the channel layer 132, the barrier layer 136, and the gate semiconductor material layer 152a of the embodiment of FIG. 13 to FIG. 18 and thus repeated description thereof is omitted.

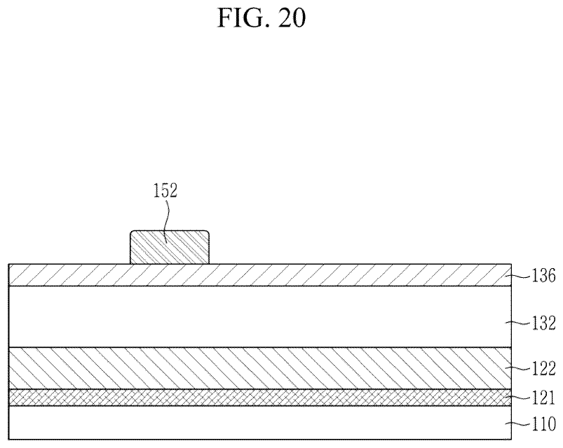

Next, as shown in FIG. 20, the gate semiconductor layer 152 may be formed by patterning the gate semiconductor material layer 152a by using a photo and etching process.

At least part of the gate semiconductor material layer 152a may be removed using a photo and etching process. Accordingly, the remaining portion of the gate semiconductor material layer 152a may become a gate semiconductor layer 152. The gate semiconductor layer 152 is positioned on the barrier layer 136.

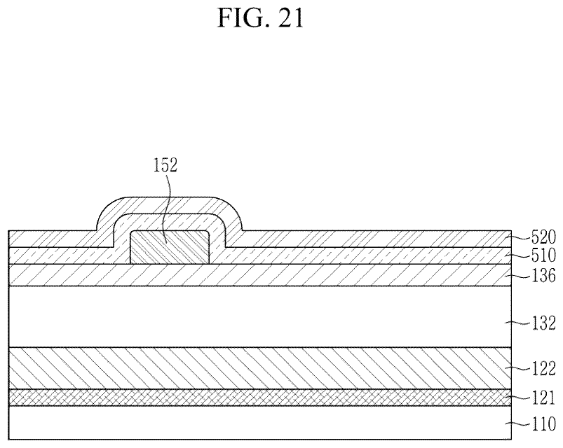

As shown in FIG. 21, a protection layer 500 may be formed on the barrier layer 136 and the gate semiconductor layer 152.

For example, a first protection layer 510 and a second protection layer 520 may be formed sequentially on the barrier layer 136 and the gate semiconductor layer 152. The first protection layer 510 and the second protection layer 520 may be formed using a deposition process. The first protection layer 510 and the second protection layer 520 may include an insulating material.

The side of the gate semiconductor layer 152 may be covered by the first protection layer 510 and the second protection layer 520. The side of the gate semiconductor layer 152 may be in contact with the first protection layer 510. A step may occur between the part of the first protection layer 510 that overlaps with the gate semiconductor layer 152 and the remaining part. Additionally, a step may occur between the portion of the second protection layer 520 that overlaps with the gate semiconductor layer 152 and the remaining portion. However, embodiments of the present disclosure are not limited to this, and in some cases, the upper surface of the first protection layer 510 and the upper surface of the second protection layer 520 may be entirely flat.

The first protection layer 510 and the second protection layer 520 may include an insulating material. The second protection layer 520 may include a different material than a material of the first protection layer 510. For example, the first protection layer 510 may include silicon oxide (SiOₓ) (1≤x≤4). Also, the first protection layer 510 may include a material such as silicon nitride (SiN), aluminum oxide (Al₂O₃), the like. Additionally, the second protection layer 520 may include silicon oxynitride (SiON), but embodiments of the present disclosure are not limited thereto. The remaining description of the first protection layer 510 and the second protection layer 520 is substantially the same as the description of the first protection layer 510 and the second protection layer 520 of the embodiment of FIG. 13 to FIG. 18, and thus repeated description thereof is omitted.

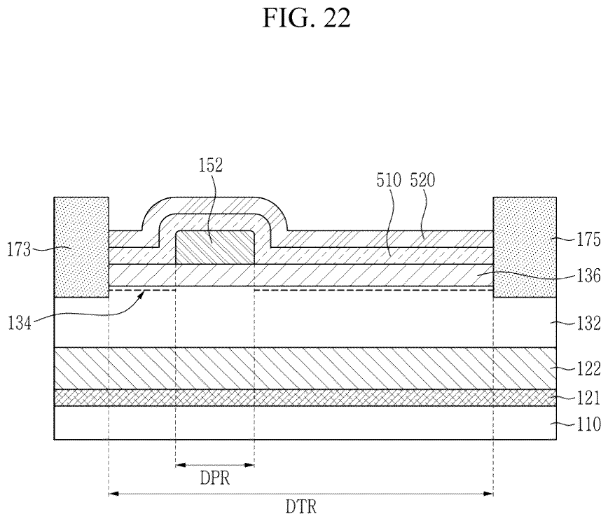

As shown in FIG. 22, trenches may be formed by patterning the protection layer 500, the barrier layer 136, and the channel layer 132, and a source electrode 173 and a drain electrode 175 may be formed within the trenches.

First, a photoresist pattern may be formed on the second protection layer 520, and by using this as a mask, the second protection layer 520, the first protection layer 510, the barrier layer 136, and the channel layer 132 may be sequentially etched to form trenches. In such case, the second protection layer 520, the first protection layer 510, and the barrier layer 136 may be penetrated by the trenches, and the upper surface of the channel layer 132 may be recessed.

Subsequently, a conductive material may be deposited on the inside of the trenches and patterned to form the source electrode 173 and the drain electrode 175. The process of forming the source electrode 173 and the drain electrode 175 is substantially the same as the process of forming the source electrode 173 and the drain electrode 175 of FIG. 18, and so repeated description thereof may be omitted.

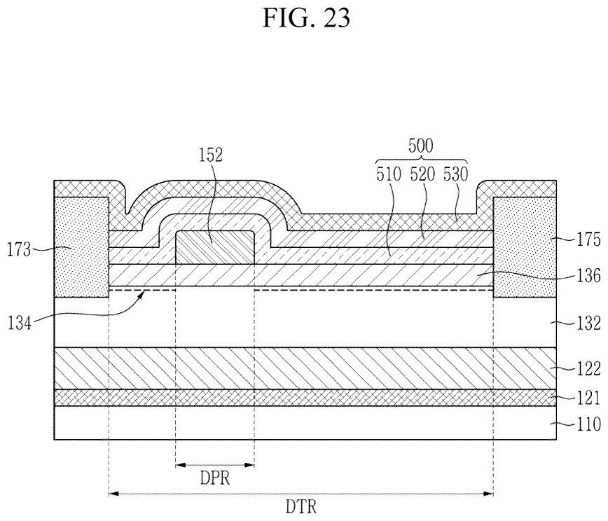

As shown in FIG. 23, a third protection layer 530 may be formed on the second protection layer 520, the source electrode 173, and the drain electrode 175. For example, the third protection layer 530 may be formed on the upper surface of the second protection layer 520, the exposed upper and side surfaces of the source electrode 173, and the upper and side surfaces of the drain electrode 175. Accordingly, the third protection layer 530 may cover the upper surface of the second protection layer 520, the upper surface of the source electrode 173, and the upper surface of the drain electrode 175.

In some embodiments, the third protection layer 530 may include an insulating material. The third protection layer 530 may include a different material than a material of the second protection layer 520. Additionally, the third protection layer 530 may include the same material as a material of the first protection layer 510, but embodiments of the present disclosure are not limited thereto. For example, the third protection layer 530 may include silicon oxide (SiOₓ) (1≤x≤4). Alternatively, the third protection layer 530 may include materials such as silicon nitride (SiN), aluminum oxide (Al₂O₃), etc.

In some embodiments, the third protection layer 530 may include a first element. For example, when the third protection layer 530 of the semiconductor device according to an embodiment includes silicon oxide (SiOₓ) (1≤x≤4), the first element may be silicon (Si). In such case, the ratio of the first element of the third protection layer 530 may increase as it moves away from the upper surface of the barrier layer 136, but embodiments of the present disclosure are not limited thereto. Additionally, the ratio of the first element of the third protection layer 530 may be greater than or equal to the ratio of the first element of the first protection layer 510.

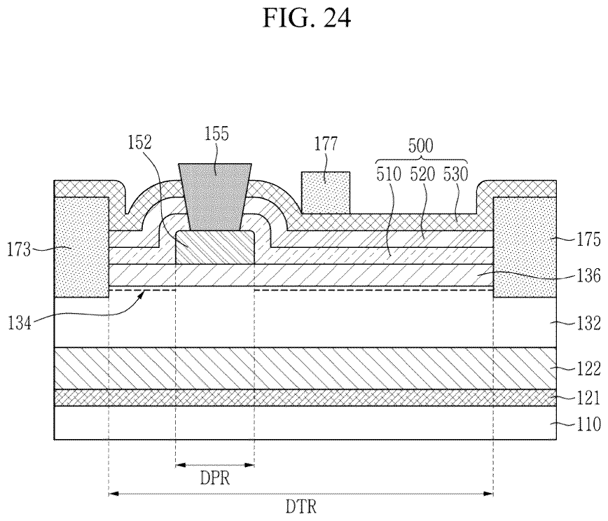

As shown in FIG. 24, a gate electrode 155 that penetrates at least a part of the first protection layer 510, the second protection layer 520, and the third protection layer 530 may be formed.

The gate electrode 155 may be electrically connected to the gate semiconductor layer 152 by penetrating the first protection layer 510, the second protection layer 520, and the third protection layer 530. The gate electrode 155 may be surrounded by the first protection layer 510, the second protection layer 520, and the third protection layer 530. That is, the side of gate electrode 155 may be in contact with the first protection layer 510, the second protection layer 520, and the third protection layer 530. The gate electrode 155 may overlap with the gate semiconductor layer 152 in the vertical direction (e.g., the thickness direction of the channel layer 132).

In such case, in the step of forming the gate electrode 155, the field dispersion layer 177 may be formed together. The field dispersion layer 177 may be positioned between the source electrode 173 and the drain electrode 175. The field dispersion layer 177 may include the same material as a material of the gate electrode 155.

Non-limiting example embodiments of the present disclosure have been described in detail above. However, the range of embodiments of the present disclosure is not limited thereto. On the contrary, it should be understood that various modifications and equivalent arrangements are covered by the spirit and scope of the present disclosure.

What is claimed is:

1. A semiconductor device comprising:
a channel layer;
a barrier layer above the channel layer and comprising a material having a energy band gap that is different from an energy band gap of the channel layer;
a gate electrode above the barrier layer,
a gate semiconductor layer between the barrier layer and the gate electrode;
a source electrode on a first side of the gate electrode, and on a first side of the channel layer and a first side of the barrier layer;
a drain electrode on a second side of the gate electrode, opposite to the first side, and on a second side of the channel layer and a second side of the barrier layer; and
a field dispersion layer connected to the source electrode and on the gate electrode, and
a protection layer between barrier layer and the field dispersion layer,
wherein the protection layer comprises:
a first protection layer above the barrier layer and comprising silicon oxide; and
a second protection layer above the first protection layer and comprising silicon oxynitride.

2. The semiconductor device of claim 1, wherein
an Si ratio of the first protection layer increases in a direction away from the barrier layer.

3. The semiconductor device of claim 1, wherein the first protection layer comprises:
a first region above the barrier layer; and
a second region above the first region, and
wherein an Si ratio in the first region is smaller than an Si ratio in the second region.

4. The semiconductor device of claim 1, wherein the protection layer further comprises:
a third protection layer between the second protection layer and the field dispersion layer, and
the third protection layer comprises a same material as a material of the first protection layer.

5. The semiconductor device of claim 4, wherein an Si ratio of the third protection layer is greater than or equal to an Si ratio of the first protection layer.

6. The semiconductor device of claim 4, wherein the third protection layer comprises:
a first region on the second protection layer; and
a second region on the first region, and
wherein an Si ratio in the first region is smaller than an Si ratio in the second region.

7. The semiconductor device of claim 5, wherein
the Si ratio of the third protection layer increases in a direction away from the barrier layer.

8. The semiconductor device of claim 1, wherein
the channel layer comprises a drift region where two-dimensional electron gases are generated between the source electrode and the drain electrode, and
the protection layer overlaps the drift region of the channel layer in a thickness direction of the channel layer.

9. The semiconductor device of claim 1, wherein
the field dispersion layer and the source electrode are in a same layer and comprise a same material as each other, and
the field dispersion layer is integrally formed with the source electrode.

10. The semiconductor device of claim 9, wherein
the gate semiconductor layer and the gate electrode overlap with the field dispersion layer in a thickness direction of the channel layer.

11. The semiconductor device of claim 1, wherein
the source electrode and the drain electrode are on respective sides of the protection layer.

12. The semiconductor device, wherein
the first protection layer is between the source electrode and the drain electrode, and
the second protection layer is between the source electrode and the drain electrode, or is on upper surfaces of the source electrode and the drain electrode.

13. A semiconductor device comprising:
a channel layer;
a barrier layer above the channel layer and comprising a material having an energy band gap that is different from an energy band gap of the channel layer;
a gate semiconductor layer above the barrier layer;
a protection layer on the barrier layer and the gate semiconductor layer;
a source electrode on a first side of the channel layer and a first side of the barrier layer; and
a drain electrode on a second side of the channel layer and a second side of the barrier layer,
wherein the protection layer comprises:
a first protection layer above the barrier layer and comprising a first element; and
a second protection layer above the first protection layer and comprising the first element and a second element different from the first element, and
wherein a ratio of the first element of the first protection layer increases in a direction away from an upper surface of the barrier layer.

14. The semiconductor device of claim 13, wherein
the first element comprises Si, and the second element comprises N.

15. The semiconductor device of claim 13, wherein the first protection layer comprises:
a first region on the barrier layer; and
a second region on the first region, and
wherein a ratio of the first element in the first region is smaller than a ratio of the first element in the second region.

16. The semiconductor device of claim 15, wherein the protection layer further comprises:
a third protection layer above the second protection layer and comprising the first element, and
a ratio of the first element of the third protection layer increases in the direction away from the upper surface of the barrier layer.

17. The semiconductor device of claim 16, wherein
a ratio of the first element of the third protection layer is greater than or equal to the ratio of the first element of the first protection layer.

18. The semiconductor device of claim 15, further comprising:
a gate electrode that penetrates the protection layer such as to be in contact with the gate semiconductor layer.

19. A semiconductor device comprising:
a substrate;
a channel layer on the substrate and comprising GaN;
a barrier layer above the channel layer and comprising AlGaN;
a gate electrode above the barrier layer and comprising a metal material;
a gate semiconductor layer between the barrier layer and the gate electrode and comprising GaN doped with a P-type impurity;
a source electrode on a first side of the gate electrode, and on a first side of the channel layer and a first side of the barrier layer;
a drain electrode on a second side of the gate electrode, opposite to the first side, and on a second side of the channel layer and a second side of the barrier layer;
a field dispersion layer on the gate electrode, the field dispersion layer in a same layer as a layer of the source electrode and formed integrally with the source electrode; and
a protection layer between the barrier layer and the field dispersion layer,
wherein the protection layer comprises:
a first protection layer on the barrier layer and comprising Si; and
a second protection layer on the first protection layer and comprising SiON, and
wherein an Si ratio of the first protection layer increases in a direction away from an upper surface of the barrier layer.

20. The semiconductor device of claim 19, wherein the protection layer further comprises:
a third protection layer between the second protection layer and the field dispersion layer, and
wherein the third protection layer comprises a same material as a material of the first protection layer.
